(19) United States
(12) Patent Application Publication
(10) Pub. No.: US 2026/0039275 A1
(43) Pub. Date: Feb. 5, 2026

(54) PIEZOELECTRIC FILM GROWTH WHILE REDUCING ELECTRICAL LOSSES FOR IMPROVED QUALITY FACTOR IN BAW FILTER

(71) Applicant: Qorvo US, Inc., Greensboro, NC (US)

(72) Inventors: Sajal Sagar Singh, Apopka, FL (US); Mohammad J. Modarres-Zadeh, Longwood, FL (US); Patrick Wayne Sadik, Longwood, FL (US); Jyothi Swaroop Sadhu, Sanford, FL (US)

(21) Appl. No.: 19/277,856

(22) Filed: Jul. 23, 2025

Related U.S. Application Data
(60) Provisional application No. 63/677,148, filed on Jul. 30, 2024.

(51) Int. Cl. H03H 9/17; H03H 3/02; H03H 9/02; H03H 9/13

(52) U.S. Cl. CPC H03H 9/175; H03H 3/02; H03H 9/02086; H03H 9/131; H03H 9/176; H03H 2003/025

(57) ABSTRACT

The present disclosure relates to a bulk acoustic wave (BAW) resonator capable of reducing electrical losses for high frequency applications without suffering extra material losses, thereby producing high-performance high frequency BAW filters, and a fabricating process to provide such BAW resonator. The disclosed BAW resonator includes a conductive reflector, a dielectric layer over the conductive reflector, a seed layer over the dielectric layer, a bottom electrode over the seed layer, a connection structure electrically connecting the bottom electrode and the conductive reflector, a piezoelectric film over the bottom electrode, and a top electrode over the piezoelectric film. Herein, a combination of the bottom electrode, the seed layer, and the dielectric layer only partially covers a top surface of the bottom reflector. At least 80% of metal grains in the bottom electrode are oriented within 3 degrees towards a thermodynamically stable orientation of metal materials in the bottom electrode.

### RELATED APPLICATIONS

This application claims the benefit of provisional patent application Ser. No. 63/677,148, filed Jul. 30, 2024, the disclosure of which is hereby incorporated herein by reference in its entirety.

### FIELD OF THE DISCLOSURE

The present disclosure relates to a bulk acoustic wave (BAW) resonator and a process for making the same, and more particularly to a BAW resonator capable of reducing electrical losses for high frequency applications without suffering extra material losses, thereby producing high-performance high frequency BAW filters, and a fabricating process to provide such BAW resonator.

### BACKGROUND

Due to their small size, high Q values, and very low insertion losses at microwave frequencies, particularly those above 1.5 Gigahertz (GHz), bulk acoustic wave (BAW) filters incorporating BAW resonators have been widely used in many modern wireless applications. In particular, the BAW filters are the filter of choice for many 3^{rd} Generation (3G) and 4^{th} Generation (4G) wireless devices, and are destined to dominate filter applications for 5th Generation (5G) wireless devices. Most of these wireless devices support cellular, wireless fidelity (Wi-Fi), Bluetooth, and/or near field communications on the same wireless device, and as such, pose extremely challenging filtering demands. While these demands keep raising the complexity of the wireless devices, there is a constant need to improve the performance of BAW resonators and BAW-based filters as well as decrease the cost and size associated therewith.

To meet filtering requirements in certain applications (e.g., 5G networks), the BAW filters operate at higher frequencies (e.g., greater than 5 GHz), which may require thin layers of piezoelectric film and electrodes in the BAW resonators. However, reducing the thickness of the electrodes may result in increased resistance and/or electrical losses, which can negatively affect the quality factor of the BAW resonators. In addition, the quality factor of the BAW resonators is also significantly affected by texture, roughness, etc. of the piezoelectric film growth.

Accordingly, there remains a need for improved BAW resonator designs that can accommodate reductions in electrode thickness to meet performance requirements (e.g., filtering requirements), while preventing increases in both the electrical losses (driven by the electrode thickness reduction) and the material losses (based on the quality of the thin piezoelectric film growth) to retain a high-quality factor value.

### SUMMARY

The present disclosure relates to a bulk acoustic wave (BAW) resonator capable of reducing electrical losses for high frequency applications without suffering extra material losses, thereby producing high-performance high frequency BAW filters, and a fabricating process to provide such BAW resonator. The disclosed BAW resonator includes a bottom reflector, a bottom dielectric layer, a seed layer, a bottom electrode, a bottom connection structure, a piezoelectric film, and a top electrode. Herein, the bottom reflector is composed of a stack of alternating high acoustic impedance conductive layers and low acoustic impedance conductive layers. The bottom dielectric layer is formed directly over the bottom reflector, and the seed layer is formed directly over the bottom dielectric layer. The bottom electrode including metal materials is directly formed over the seed layer. A periphery of the bottom electrode, a periphery of the seed layer, and a periphery of the bottom dielectric layer are coincidental. A combination of the bottom electrode, the seed layer, and the bottom dielectric layer does not fully cover a top surface of the bottom reflector. At least 80% of metal grains in the bottom electrode are oriented within 3 degrees towards a thermodynamically stable orientation of the metal materials in the bottom electrode. The bottom connection structure is configured to provide an electrical connection between the bottom electrode and the bottom reflector, and has a different layer configuration than the bottom electrode. The piezoelectric film is formed over the bottom electrode, while the top electrode is formed over the piezoelectric film and aligned with the bottom electrode.

In one embodiment of the BAW resonator, the seed layer is formed of aluminum nitride (AlN). The bottom electrode is composed of at least a first bottom electrode layer and a second bottom electrode layer. Herein, the second bottom electrode layer directly and fully covers a top surface of the seed layer and is formed of aluminum copper (AlCu), while the first bottom electrode layer fully covers a top surface of the second bottom electrode layer and is formed of tungsten (W), molybdenum (Mo), or platinum (Pt). The piezoelectric film is formed of one of a group consisting of AlN, scandium-doped aluminum nitride (ScAlN), magnesium hydrofluoric acid aluminum nitride (MgHfAlN), magnesium zirconium aluminum nitride (MgZrAlN), and magnesium titanium aluminum nitride (MgTiAlN).

In one embodiment of the BAW resonator, the bottom electrode has a thickness as thin as 50 nm.

In one embodiment of the BAW resonator, the piezoelectric film has a thickness between 0.1 μm and 1.4 μm.

In one embodiment of the BAW resonator, the bottom connection structure directly covers side surfaces of the bottom electrode, side surfaces of the seed layer, and side surfaces of the bottom dielectric layer, and extends directly over portions of the top surface of the bottom reflector, which are not covered by the combination of the bottom electrode, the seed layer, and the bottom dielectric layer. Furthermore, the bottom connection structure includes one or more metal materials.

In one embodiment of the BAW resonator, the bottom connection structure includes a first connection layer and a second connection layer, each of which is formed of a metal material. The first connection layer directly covers the side surfaces of the bottom electrode, the side surfaces of the seed layer, and the side surfaces of the bottom dielectric layer, and extends directly over the portions of the top surface of the bottom reflector, which are not covered by the combination of the bottom electrode, the seed layer, and the bottom dielectric layer. The second connection layer directly and fully covers the first connection layer.

In one embodiment of the BAW resonator, the first connection layer is formed of aluminum (Al), and the second connection layer is formed of W.

In one embodiment of the BAW resonator, the bottom connection structure further includes a barrier layer formed of AlN, which directly and fully covers the second connection layer.

According to one embodiment, the BAW resonator further includes a substrate, and an electrostatic discharge (ESD) protection layer. Herein, the ESD protection layer is an electrically insulating layer and formed over the substrate. The bottom reflector is formed over the ESD protection layer, such that the ESD protection layer isolates the substrate from the bottom reflector.

In one embodiment of the BAW resonator, the ESD protection layer is formed of aluminum nitride (AlN), silicon oxide, or silicon nitride.

According to one embodiment, the BAW resonator further includes a bottom isolation section filled vertically between the piezoelectric film and the ESD protection layer to surround a combination of the bottom reflector, the bottom dielectric layer, the seed layer, the bottom electrode, and the bottom connection structure. The bottom isolation section is formed of silicon oxide.

In one embodiment of the BAW resonator, the high acoustic impedance conductive layers are formed of W, Mo, or Pt, while the low acoustic impedance conductive layers are formed of Al or titanium (Ti).

In one embodiment of the BAW resonator, the top electrode is composed of at least a first top electrode layer and a second top electrode layer. Herein, the first top electrode layer is formed directly over the piezoelectric film, while the second top electrode layer is formed over the first top electrode layer. The first top electrode layer is formed of W, Mo, or Pt, and the second top electrode layer is formed of AlCu.

According to one embodiment, the BAW resonator further includes a border ring (BO) formed on or within the top electrode to suppress spurious modes.

According to one embodiment, the BAW resonator further includes a top reflector. Herein, the top reflector includes a stack of alternating high acoustic impedance conductive layers and low acoustic impedance conductive layers. The top reflector is formed over and electrically connected to the top electrode.

According to one embodiment, the BAW resonator further includes a top dielectric layer and a top connection structure. Herein, the top dielectric layer is formed directly over and partially covers the top electrode, such that a peripheral portion of a top surface of the top electrode is not covered by the top dielectric layer. The top reflector is formed directly over the top dielectric layer. The top connection structure extends from a peripheral portion of a bottom surface of the top reflector, along sides of the top dielectric layer, and toward the peripheral portion of the top surface of the top electrode, which is not covered by the top dielectric layer. The top connection structure is configured to electrically connect the top electrode with the top reflector.

In one embodiment of the BAW resonator, the top connection structure and a bottommost one of the alternating high acoustic impedance conductive layers and low acoustic impedance conductive layers are formed of a same conductive material.

According to one embodiment, an exemplary method of fabricating a BAW resonator includes depositing an intact bottom dielectric layer to directly and fully cover a top surface of a bottom reflector, which includes a stack of alternating high acoustic impedance conductive layers and low acoustic impedance conductive layers. Next, an intact seed layer is deposited in order to directly and fully cover the intact bottom dielectric layer, and an intact bottom electrode in-situ is deposited in order to directly and fully cover the intact seed layer. Herein, the intact bottom electrode includes metal materials, and at least 80% of metal grains in the intact bottom electrode are oriented within 3 degrees towards a thermodynamically stable orientation of the metal materials in the bottom electrode. A combination of the intact bottom dielectric layer, the intact seed layer, and the intact bottom electrode is then selectively removed to expose portions of the top surface of the bottom reflector. The intact bottom dielectric layer, the intact seed layer, and the intact bottom electrode are converted into a bottom dielectric layer, a seed layer, and a bottom electrode, respectively. A bottom connection structure is formed to provide an electrical connection between the bottom electrode and the bottom reflector. The bottom connection structure directly covers side surfaces of the bottom electrode, side surfaces of the seed layer, and side surfaces of the bottom dielectric layer, and extends directly over the exposed portions of the top surface of the bottom reflector, while a top surface of the bottom electrode is not covered by the bottom connection structure. A piezoelectric film is formed over the top surface of the bottom electrode.

In one embodiment of the method, forming the bottom connection structure includes forming an intact bottom connection structure, which covers the top surface of the bottom electrode, extends along the side surfaces of the bottom electrode, the side surfaces of the seed layer, and the side surfaces of the bottom dielectric layer, and extends directly over the exposed portions of the top surface of the bottom reflector. Forming the bottom connection structure also includes performing a polishing step to remove a top portion of the intact bottom connection structure to expose the top surface of the bottom electrode, where the intact bottom connection structure is converted into the bottom connection structure.

According to one embodiment, the method further includes providing a substrate, forming an ESD protection layer over the substrate, and forming a bottom isolation section. Herein, the bottom reflector is formed over the ESD protection layer, and the bottom isolation section is formed after the intact bottom connection structure is formed. The bottom isolation section is formed over the ESD protection layer to completely encapsulate a combination of the bottom reflector, the bottom dielectric layer, the seed layer, the bottom electrode, and the intact bottom connection structure. The polishing step is performed to thin down the bottom isolation section until the top portion of the intact bottom connection structure is removed, thereby exposing the top surface of the bottom electrode.

According to one embodiment, the method further includes forming a top electrode, which is over the piezoelectric film and aligned with the bottom electrode.

In one embodiment of the method, the bottom connection structure includes a first connection layer and a second connection layer, each of which is formed of a metal material. The first connection layer directly covers the side surfaces of the bottom electrode, the side surfaces of the seed layer, and the side surfaces of the bottom dielectric layer, and extends directly over the exposed portions of the top surface of the bottom reflector. The second connection layer directly and fully covers the first connection layer. The first connection layer is formed of Al, while the second connection layer is formed of W.

According to one embodiment, a system includes radio-frequency (RF) input circuitry, RF output circuitry, and filter circuitry connected between the RF input circuitry and the RF output circuitry. Herein, the filter circuitry has at least one BAW resonator, which includes a bottom reflector, a bottom dielectric layer, a seed layer, a bottom electrode, a bottom connection structure, a piezoelectric film, and a top electrode. Herein, the bottom reflector is composed of a stack of alternating high acoustic impedance conductive layers and low acoustic impedance conductive layers. The bottom dielectric layer is formed directly over the bottom reflector, and the seed layer is formed directly over the bottom dielectric layer. The bottom electrode including metal materials is directly formed over the seed layer. A periphery of the bottom electrode, a periphery of the seed layer, and a periphery of the bottom dielectric layer are coincidental. A combination of the bottom electrode, the seed layer, and the bottom dielectric layer does not fully cover a top surface of the bottom reflector. At least 80% of metal grains in the bottom electrode are oriented within 3 degrees towards a thermodynamically stable orientation of the metal materials in the bottom electrode. The bottom connection structure is configured to provide an electrical connection between the bottom electrode and the bottom reflector. The piezoelectric film is formed over the bottom electrode, while the top electrode is formed over the piezoelectric film and aligned with the bottom electrode.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a diagram illustrating a conventional bulk acoustic wave (BAW) resonator.

FIG. 2 is a diagram graphically illustrating the magnitude and phase of the electrical impedance as a function of the frequency for a relatively ideal BAW resonator.

FIGS. 3A-3C are diagrams graphically illustrating phase curves for various conventional BAW resonators.

FIG. 4 is a diagram illustrating a conventional BAW resonator with a top electrode including a border ring (BO).

FIG. 5A is a schematic of a conventional ladder network.

FIGS. 5B and 5C are graphs of a frequency response for BAW resonators in the conventional ladder network of FIG. 5A and a frequency response for the conventional ladder network of FIG. 5A.

FIGS. 6A-6E are circuit equivalents for the ladder network of FIG. 5A at the frequency points 1, 2, 3, 4, and 5, which are identified in FIG. 5C.

FIG. 7 is a cross-sectional diagram illustrating a high frequency BAW resonator, which enables a reduction in electrical losses.

FIG. 8 illustrates an electron back-scatter diffraction (EBSD) analysis of a bottom electrode of the BAW resonator shown in FIG. 7.

FIGS. 9A and 9B illustrate abnormally oriented grains (AOGs) of a piezoelectric film grown on the bottom electrode of the BAW resonator shown in FIG. 7.

FIG. 10 is a cross-sectional diagram illustrating an exemplary BAW resonator capable of reducing electrical losses for high frequency applications without suffering extra material losses according to some embodiments of the present disclosure.

FIG. 11 illustrates an EBSD analysis of a bottom electrode of the BAW resonator shown in FIG. 10.

FIG. 12 illustrates an SEM image of AOGs of a piezoelectric film grown on the bottom electrode of the BAW resonator shown in FIG. 10.

FIGS. 13A-13K show an exemplary fabricating process that illustrates steps to provide the exemplary BAW resonator shown in FIG. 10.

FIG. 14 illustrates the BAW resonator having two electrically conductive reflectors according to some embodiments of the present disclosure.

FIG. 15 illustrates a block diagram of an exemplary system that includes at least one BAW device shown in FIG. 10 or FIG. 14.

FIG. 16 illustrates a block diagram of an exemplary communication device that includes at least one BAW device shown in FIG. 10 or FIG. 14.

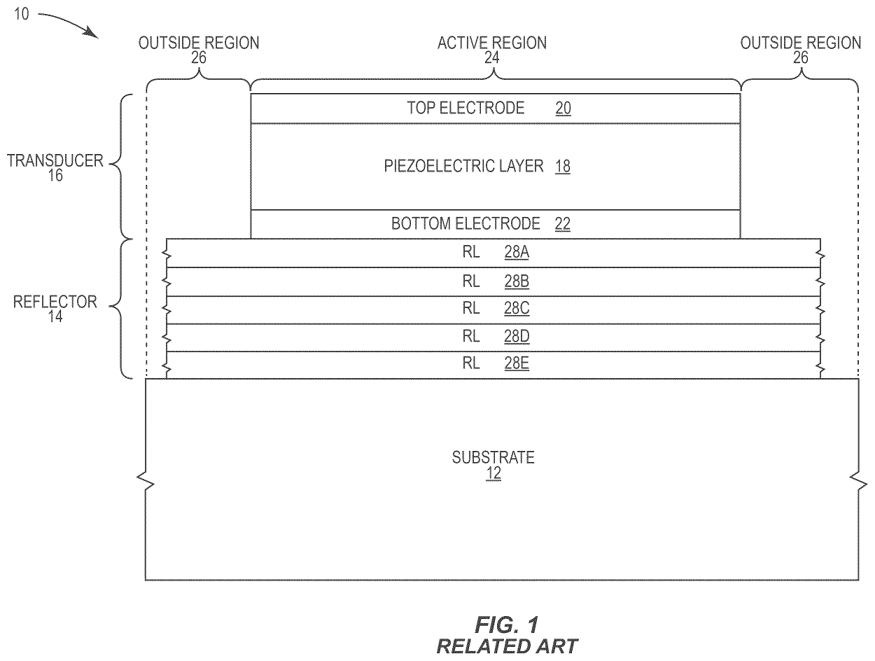

It will be understood that for clear illustrations, FIGS. 1-16 may not be drawn to scale.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to a bulk acoustic wave (BAW) resonator that is capable of meeting performance requirements (e.g., high frequency filtering requirements) while preventing increases in both electrical losses and material losses leading to high performance (e.g., high quality factor) BAW filters. Herein, the disclosed BAW resonator utilizes thin layers of piezoelectric film and electrodes to achieve high frequency requirements, and utilizes an electrical connection between a bottom electrode and a reflector to reduce the electrical losses (reduced resistance). In addition, the thin bottom electrode and the electrical connection between the thin bottom electrode and the reflector do not have a negative impact on growth quality of the piezoelectric film, which can significantly affect the quality factor of the BAW resonator.

Prior to delving into the details of these concepts, an overview of BAW resonators and filters that employ BAW resonators is provided. The BAW resonators are used in many high-frequency filter applications. An exemplary BAW resonator 10 is illustrated in FIG. 1. The BAW resonator 10 is a solidly mounted resonator (SMR) type BAW resonator 10 and generally includes a substrate 12, a reflector 14 mounted over the substrate 12, and a transducer 16 mounted over the reflector 14. The transducer 16 rests on the reflector 14 and includes a piezoelectric layer 18, which is sandwiched between a top electrode 20 and a bottom electrode 22. The top and bottom electrodes 20, 22 may be formed of tungsten (W), molybdenum (Mo), platinum (Pt), or like material, and the piezoelectric layer 18 may be formed of aluminum nitride (AlN), zinc oxide (ZnO) or other appropriate piezoelectric material. Although shown in FIG. 1 as including a single layer, the piezoelectric layer 18, the top electrode 20, and/or the bottom electrode 22 may include multiple layers of the same material, multiple layers in which at least two layers are different materials, or multiple layers in which each layer is a different material.

The BAW resonator 10 is divided into an active region 24 and an outside region 26. The active region 24 generally corresponds to the section of the BAW resonator 10 where the top and bottom electrodes 20, 22 overlap and also includes the layers below the overlapping top and bottom electrodes 20, 22.

The outside region 26 corresponds to the section of the BAW resonator 10 that surrounds the active region 24.

For the BAW resonator 10, applying electrical signals across the top electrode 20 and the bottom electrode 22 excites acoustic waves in the piezoelectric layer 18. These acoustic waves primarily propagate vertically. A primary goal in BAW resonator design is to confine these vertically propagating acoustic waves in the transducer 16. Acoustic waves traveling upward are reflected back into the transducer 16 by an air-metal boundary at a top surface of the top electrode 20. Acoustic waves traveling downward are reflected back into the transducer 16 by the reflector 14, or by an air cavity, which is provided just below the transducer 16 in a film bulk acoustic resonator (FBAR).

The reflector 14 is typically formed by a stack of reflector layers (RLs) 28A through 28E (referred to generally as reflector layers 28), which alternate in material composition to produce a significant reflection coefficient at the junction of adjacent reflector layers 28. The reflector layers 28 alternate between materials having high and low acoustic impedances, such as W and silicon dioxide (SiO₂). While only five reflector layers 28 are illustrated in FIG. 1, the number of reflector layers 28 and the structure of the reflector 14 will vary from one design to another.

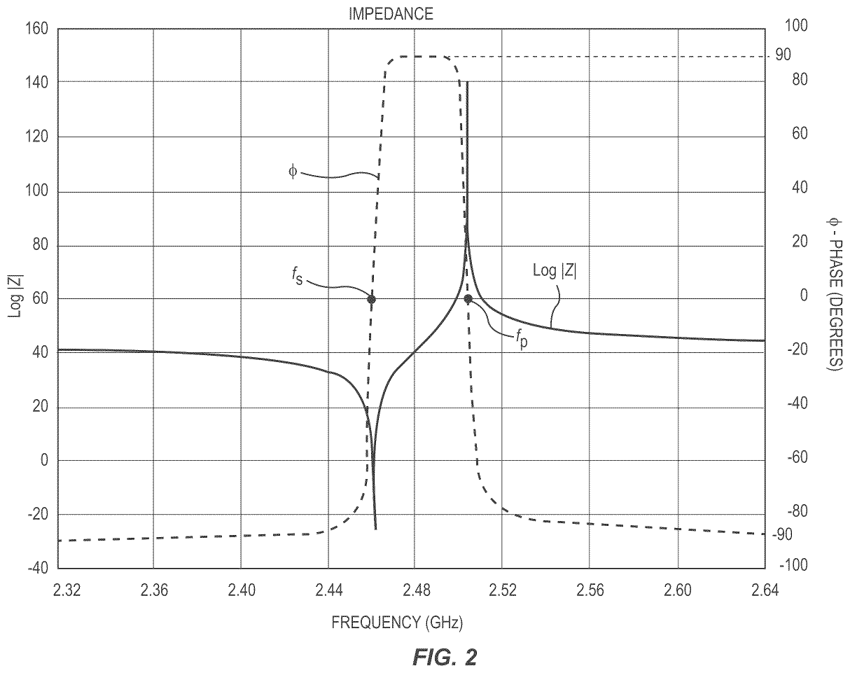

The magnitude (Z) and phase (ϕ) of the electrical impedance as a function of the frequency (GHz) for a relatively ideal BAW resonator 10 is provided in FIG. 2. The magnitude (Z) of the electrical impedance is illustrated by the solid line, while the phase (ϕ) of the electrical impedance is illustrated by the dashed line. A unique feature of the BAW resonator 10 is that it has both a resonance frequency and an antiresonance frequency. The resonance frequency is typically referred to as the series resonance frequency (fₛ), and the antiresonance frequency is typically referred to as the parallel resonance frequency (fₚ). The series resonance frequency (fₛ) occurs when the magnitude of the impedance, or reactance, of the BAW resonator 10 approaches zero. The parallel resonance frequency (fₚ) occurs when the magnitude of the impedance, or reactance, of the BAW resonator 10 peaks at a significantly high level. In general, the series resonance frequency (fₛ) is a function of the thickness or height of the piezoelectric layer 18 and the mass of the top and bottom electrodes 20, 22.

For the phase (ϕ), the BAW resonator 10 acts like an inductance that provides a 90° phase shift between the series resonance frequency (fₛ) and the parallel resonance frequency (fₚ). In contrast, the BAW resonator 10 acts like a capacitance that provides a −90° phase shift below the series resonance frequency (fₛ) and above the parallel resonance frequency (fₚ). The BAW resonator 10 presents a very low, near zero, resistance at the series resonance frequency (fₛ), and a very high resistance at the parallel resonance frequency (fₚ). The electrical nature of the BAW resonator 10 lends itself to the realization of a very high-quality factor (Q) inductance over a relatively short range of frequencies, which has proven to be very beneficial in high frequency filter networks, especially those operating at frequencies around 1.8 GHz and above.

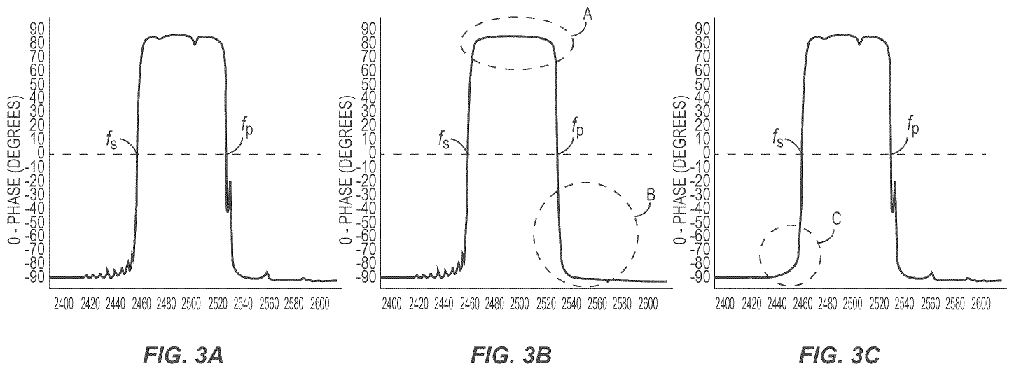

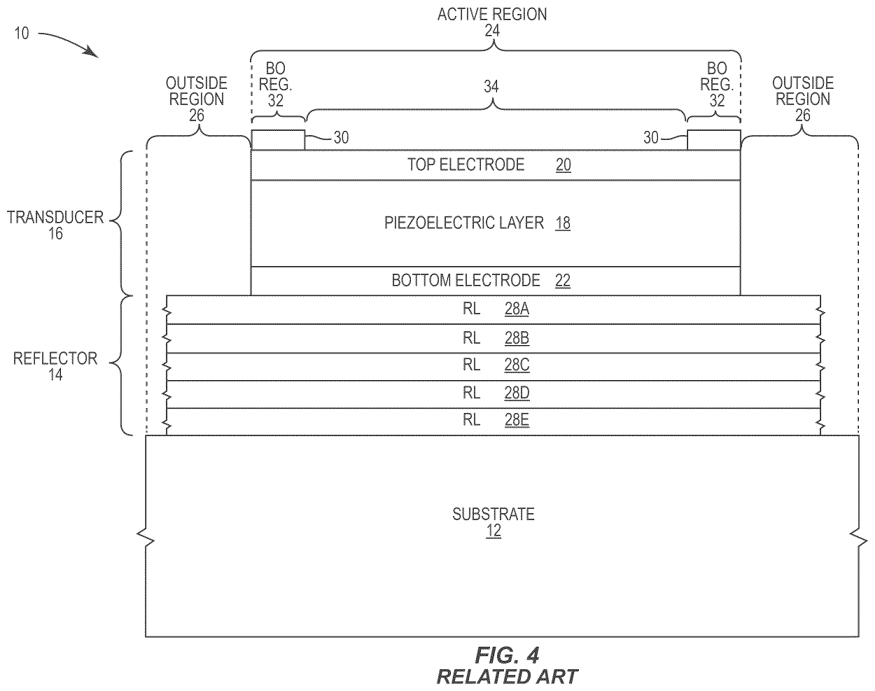

Unfortunately, the phase (ϕ) curve of FIG. 2 is representative of an ideal phase curve. In reality, approaching this ideal is challenging. A typical phase curve for the BAW resonator 10 of FIG. 1 is illustrated in FIG. 3A. Instead of being a smooth curve, the phase curve of FIG. 3A includes a ripple below the series resonance frequency (fₛ), between the series resonance frequency (fₛ) and the parallel resonance frequency (fₚ), and above the parallel resonance frequency (fₚ). The ripple is the result of spurious modes, which are caused by spurious resonances that occur in corresponding frequencies. While the vast majority of the acoustic waves in the BAW resonator 10 propagate vertically, various boundary conditions about the transducer 16 result in the propagation of lateral (horizontal) acoustic waves, which are referred to as lateral standing waves. The presence of these lateral standing waves reduces the potential quality factor (Q) associated with the BAW resonator 10.

As illustrated in FIG. 4, a border ring (BO) ring 30 is formed on or within (not shown) the top electrode 20 to suppress certain spurious modes. The spurious modes that are suppressed by the BO ring 30 are those above the series resonance frequency (fₛ), as highlighted by circles A and B in the phase curve of FIG. 3B. Circle A shows a suppression of the ripple, and thus the spurious mode, in the passband of the phase curve, which resides between the series resonance frequency (fₛ) and the parallel resonance frequency (fₚ). Circle B shows suppression of the ripple, and thus the spurious modes, above the parallel resonance frequency (fₚ). Notably, the spurious mode in the upper shoulder of the passband, which is just below the parallel resonance frequency (fₚ), and the spurious modes above the passband are suppressed, as evidenced by the smooth or substantially ripple free phase curve between the series resonance frequency (fₛ) and the parallel resonance frequency (fₚ) and above the parallel resonance frequency (fₚ).

The BO ring 30 corresponds to a mass loading of a portion of the top electrode 20 that extends about a periphery of the active region 24. In this regard, the BO ring 30 with mass loading forms a raised frame that is arranged about a periphery of the top electrode 20. The BO ring 30 may correspond to a thickened portion of the top electrode 20 or the application of additional layers of an appropriate material over the top electrode 20. The portion of the BAW resonator 10 that includes and resides below the BO ring 30 is referred to as a BO region 32. Accordingly, the BO region 32 corresponds to an outer perimeter portion of the active region 24 and resides inside the active region 24. In addition, a central region 34 of the BAW resonator 10 is defined laterally inside of the BO region 32 and is not covered by the BO ring 30.

While the BO ring 30 is effective at suppressing spurious modes above the series resonance frequency (fₛ), the BO ring 30 has little or no impact on those spurious modes below the series resonance frequency (fₛ), as shown in FIG. 3B. A technique referred to as apodization is often used to suppress the spurious modes that fall below the series resonance frequency (fₛ).

Apodization works to avoid, or at least significantly reduce, any lateral symmetry in the BAW resonator 10, or at least in the transducer 16 thereof. Lateral symmetry corresponds to the footprint of the transducer 16, and avoiding the lateral symmetry corresponds to avoiding symmetry associated with the sides of the footprint. For example, one may choose a footprint that corresponds to a pentagon instead of a square or rectangle. Avoiding symmetry helps reduce the presence of lateral standing waves in the transducer 16. Circle C of FIG. 3C illustrates the effect of apodization in which the spurious modes below the series resonance frequency (fₛ) are suppressed. Assuming that no BO ring 30 is provided, one can readily see in FIG. 3C that apodization fails to suppress those spurious modes above the series resonance frequency (fₛ). As such, the typical BAW resonator 10 employs both apodization and the BO ring 30.

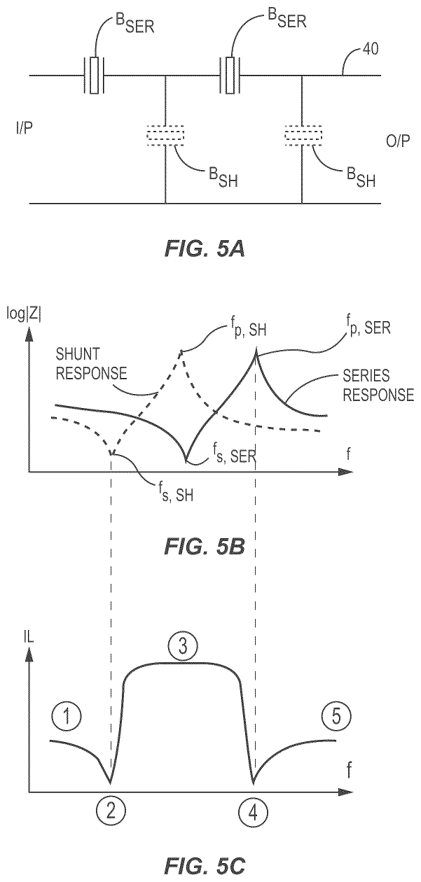

As noted above, BAW resonators 10 are often used in filter networks that operate at high frequencies and require high Q values. A basic ladder network 40 is illustrated in FIG. 5A. The ladder network 40 includes two series resonators B_{SER} and two shunt resonators B_{SH}, which are arranged in a traditional ladder configuration. Typically, the series resonators B_{SER} have the same or similar first frequency response, and the shunt resonators B_{SH} have the same or similar second frequency response, which is different than the first frequency response, as shown in FIG. 5B. In many applications, the shunt resonators B_{SH} detune a version of the series resonators B_{SER}. As a result, the frequency responses for the series resonators B_{SER} and the shunt resonators B_{SH} are generally very similar, yet shift relative to one another such that the parallel resonance frequency (f_{P,SH}), of the shunt resonators approximates the series resonance frequency (f_{S,SER}), of the series resonators B_{SER}. Note that the series resonance frequency (f_{S,SH}) of the shunt resonators B_{SH} is less than the series resonance frequency (f_{S,SER}) of the series resonators B_{SER}. The parallel resonance frequency (f_{P,SH}) of the shunt resonators B_{SH} is less than the parallel resonance frequency (f_{P,SER}) of the series resonators B_{SER}.

FIG. 5C is associated with FIG. 5B and illustrates the response of the ladder network 40. The series resonance frequency (f_{S,SH}) of the shunt resonators B_{SH} corresponds to the low side of the passband's skirt (phase 2), and the parallel resonance frequency (f_{P,SER}) of the series resonators B_{SER} corresponds to the high side of the passband's skirt (phase 4). The substantially aligned series resonance frequency (f_{S,SER}) of the series resonators B_{SER} and the parallel resonance frequency (f_{P,SH}) of the shunt resonators B_{SH} fall within the passband.

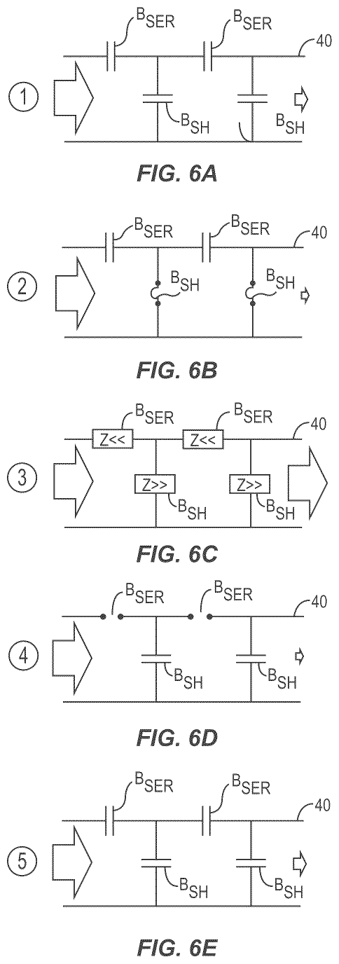

FIGS. 6A through 6E provide circuit equivalents for the five phases of the response of the ladder network 40. During the first phase (phase 1, FIGS. 5C, 6A), the ladder network 40 functions to attenuate the input signal. As the series resonance frequency (f_{S,SH}) of the shunt resonators B_{SH} is approached, the impedance of the shunt resonators B_{SH} drops precipitously, such that the shunt resonators B_{SH} essentially provide a short to ground at the series resonance frequency (f_{S,SH}) of the shunt resonators (phase 2, FIGS. 5C, 6B). At the series resonance frequency (f_{S,SH}) of the shunt resonators B_{SH} (phase 2), the input signal is essentially blocked from the output of the ladder network 40.

Between the series resonance frequency (f_{S,SH}) of the shunt resonators B_{SH} and the parallel resonance frequency (f_{P,SER}) of the series resonators B_{SER}, which corresponds to the passband, the input signal is passed to the output with relatively little or no attenuation (phase 3, FIGS. 5C, 6C). Within the passband, the series resonators B_{SER} present a relatively low impedance, while the shunt resonators B_{SH} present a relatively high impedance, wherein the combination of the two leads to a flat passband with steep low and high-side skirts. As the parallel resonance frequency (f_{P,SER}) of the series resonators B_{SER} is approached, the impedance of the series resonators B_{SER} becomes very high, such that the series resonators B_{SER} essentially present themselves as open at the parallel resonance frequency (f_{P,SER}) of the series resonators (phase 4, FIGS. 5C, 6D). At the parallel resonance frequency (f_{P,SER}) of the series resonators B_{SER} (phase 4), the input signal is again essentially blocked from the output of the ladder network 40. During the final phase (phase 5, FIGS. 50, 6E), the ladder network 40 functions to attenuate the input signal, in a similar fashion to that provided in phase 1. As the parallel resonance frequency (f_{P,SER}) of the series resonators

B_{SER} is passed, the impedance of the series resonators B_{SER} decreases, and the impedance of the shunt resonators B_{SH} normalizes. Thus, the ladder network 40 functions to provide a high Q passband between the series resonance frequency (f_{S,SH}) of the shunt resonators B_{SH} and the parallel resonance frequency (f_{P,SER}) of the series resonators B_{SER}. The ladder network 40 provides extremely high attenuation at both the series resonance frequency (f_{S,SH}) of the shunt resonators B_{SH} and the parallel resonance frequency (f_{P,SER}) of the series resonators. The ladder network 40 provides good attenuation below the series resonance frequency (f_{S,SH}) of the shunt resonators B_{SH} and above the parallel resonance frequency (f_{P,SER}) of the series resonators B_{SER}.

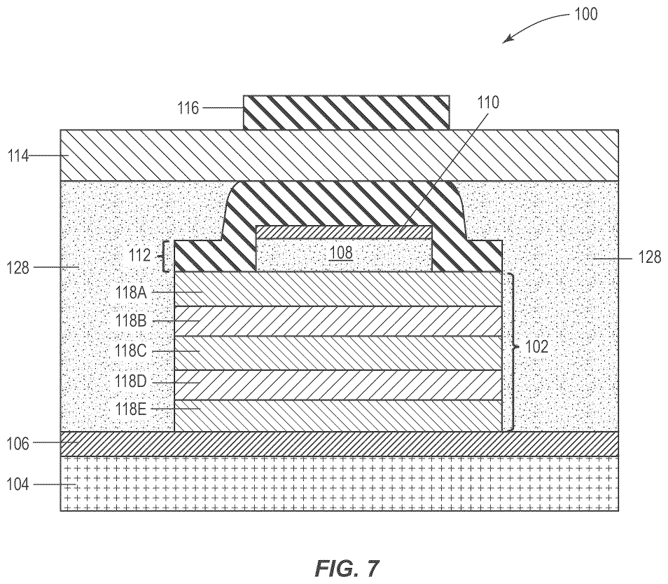

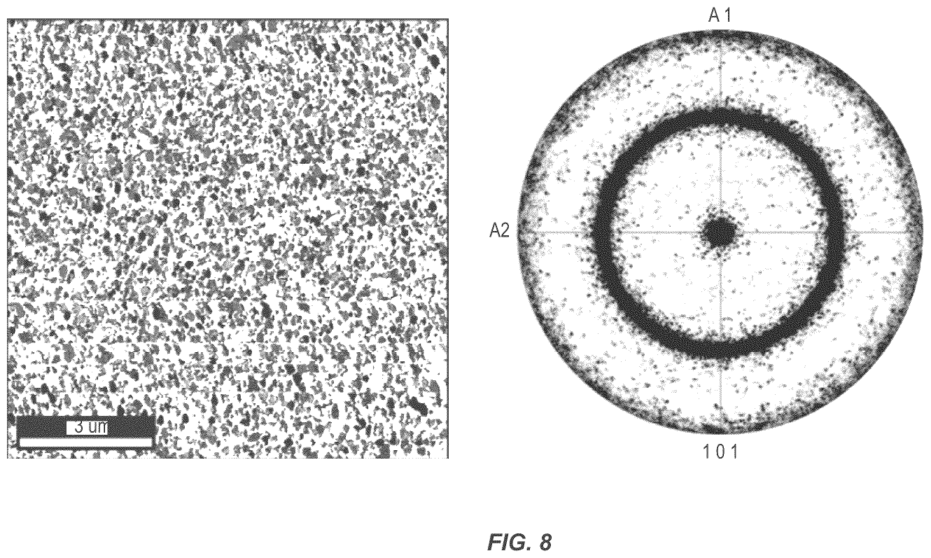

In order to meet filtering requirements in certain applications (e.g., 5G networks), the BAW filters need to operate at higher frequencies (e.g., greater than 5 GHz), which may require thin layers of the piezoelectric film and the top and bottom electrodes (e.g., frequency scale as 1/thickness) in the BAW resonators. However, reducing the thickness of the electrodes may result in increased resistance and/or electrical loss. FIG. 7 illustrates a cross-sectional diagram of a high frequency BAW resonator 100, which meets filtering requirements and enables a reduction in resistance and/or electrical loss. For the purpose of this illustration, the high frequency BAW resonator 100 includes a bottom reflector 102, a substrate 104 underneath the bottom reflector 102, an electrostatic discharge (ESD) protection layer 106 vertically between the substrate 104 and the bottom reflector 102, a dielectric layer 108 over the bottom reflector 102, a seed layer 110 over the dielectric layer 108, a bottom electrode 112, a piezoelectric film 114 over the bottom electrode 112, and a top electrode 116.

The substrate 104 is formed of a semiconductor material. The ESD protection layer 106 is an electrically insulating layer configured to isolate the substrate 104 from the bottom reflector 102 formed over the ESD protection layer. The bottom reflector 102 may be a Bragg reflector and is composed of a stack of reflector layers 118A through 118E (referred to generally as reflector layers 118), each of which is electrically conductive. The reflector layers 118 alternate between different metal materials having high and low acoustic impedances, so as to produce a significant reflection coefficient at a junction of adjacent reflector layers 118. The dielectric layer 108 is formed directly over a first reflector layer 118A without fully covering a top surface of the first reflector layer 118A (i.e., a top surface of the bottom reflector 102). The dielectric layer 108 may be formed of SiO₂ and is configured to compensate for a frequency shift of the BAW resonator 100 caused by the bottom metal reflector 102. The seed layer 110 is formed over a top surface of the dielectric layer 108 without extending laterally beyond the dielectric layer 108. The seed layer 110 may be formed of AlN and is configured to accommodate the bottom electrode 112. The bottom electrode 112 fully covers a top surface of the seed layer 110, extends along sides of the seed layer 110 and the dielectric layer 108, and is contact with portions of the top surface of the first reflector layer 118A that are not covered by the dielectric layer 108/the seed layer 110. The bottom electrode 112 may be composed of aluminum copper (AlCu) and one of W, Mo, and Pt. As such, the bottom electrode 112 is electrically connected with the conductive bottom reflector 102.

It is known that within a BAW resonator, a thin thickness of an electrode will result in a relatively high resistance and/or electrical loss (leading to low Q factors), since a current has only a narrow conductive path to pass through. However, simply increasing the thickness of the electrode may not meet certain acoustic performance requirements (e.g., high frequency filtering). It is because the resonance frequency of the BAW resonator is very sensitive to the thickness of the electrode. A small thickness increment of the electrode may result in a significant reduction in frequency. A thickness of a reflector of the BAW resonator, on the other hand, has a relatively small impact on the resonate frequency. Therefore, electrically connecting the electrode to the reflector can achieve a thicker effective electrode (electrode+reflector) for reduced resistance/electrical loss without significantly affecting the resonate frequency range. Herein, the bottom electrode 112 is electrically connected to the bottom reflector 102 to achieve a thicker effective bottom electrode, such that the current received from the bottom electrode 112 can pass through a combination of the bottom electrode 112 and the bottom reflector 102. Since the current will also pass through the bottom reflector 102, the ESD protection layer 106 is needed to isolate the bottom reflector 102 from the substrate 104, and in consequence, to avoid undesired shorting to other electronic components formed on the substrate 104 (not shown).

The piezoelectric film 114 is formed over the bottom electrode 112, and the top electrode 116 is formed over the piezoelectric film 114. It is known that the quality of piezoelectric film growth can significantly affect a quality factor of one BAW resonator. Within the BAW resonator, the quality of piezoelectric film growth depends strongly on the nature of the incoming layers such as a bottom electrode (on which the piezoelectric film is grown). Any roughness or imperfections in growth orientation in the incoming layer can directly and negatively affect the piezoelectric film growth. Therefore, it is important to ensure that in addition to parameters of the piezoelectric film growth itself, other layers also need to be optimized.

Within the BAW resonator 100, a quality/condition of the seed layer 110 directly affects deposition of the bottom electrode 112. Ideally, the seed layer 110 and the bottom electrode 112 should be deposited in-situ (i.e., the depositions of the seed layer 110 and the bottom electrode 112 are continuous without any other processing steps in between) so as to maintain their pristine nature. However, in order to ensure the electrical connection between the bottom electrode 112 and the bottom reflector 102, typically, the seed layer 110 needs to be deposited ex-situ compared to the bottom electrode 112. The seed layer 110 may be provided by depositing an initial seed layer on an initial dielectric layer fully covering the top surface of the bottom reflector 102 (not shown), and subsequently pattern etching both the initial seed layer and the initial dielectric layer, so as to expose some portions of the top surface of the bottom reflector 102. After the etching process, the bottom electrode 112 is then deposited in order to electrically connect to the bottom reflector 102. However, such ex-situ deposition of the seed layer 110 leads to a low-quality deposition of the bottom electrode 112. In addition, the bottom electrode 112 is not consistently deposited on one flat surface, but deposited to different surfaces (e.g., top and side surfaces) facing different directions, which may also impact the deposition quality of the bottom electrode 112. Due to the low-quality deposition of the bottom electrode 112, the piezoelectric film 114 grown on the bottom electrode 112 cannot achieve a high quality. In consequence, although the BAW resonator 100 can meet high frequency filtering requirements (e.g., thin thicknesses of the bottom electrode 112 and the piezoelectric film 114) without increasing the resistance/electrical losses (by electrical connection between the thin bottom electrode and the bottom reflector 102), the BAW resonator 100 still suffers material losses because of the poor growth quality of the piezoelectric film 114.

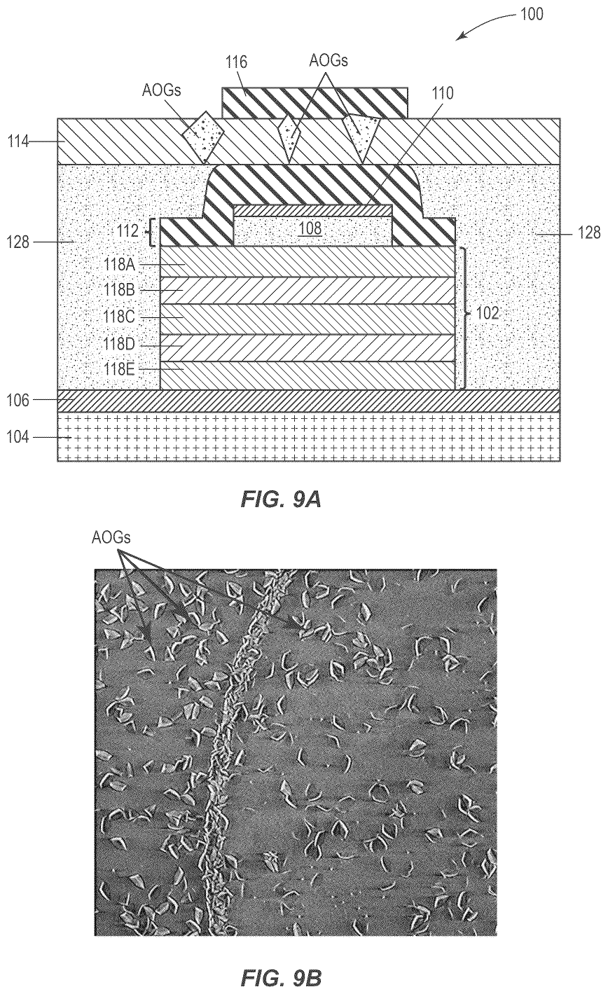

FIG. 8 illustrates electron back-scatter diffraction (EBSD) analysis of the bottom electrode 112. Herein, only 60% of metal crystals within the bottom electrode 112 are oriented within 3 degrees to the thermodynamically stable orientation of the metal materials within the bottom electrode 112. For a high-quality piezoelectric film growth, this number should be greater than 80%. FIGS. 9A-9B illustrate abnormally oriented grains (AOGs) of the piezoelectric film 114 grown on the bottom electrode 112. FIG. 9A is a schematic illustration, while FIG. 9B illustrates a scanning electron microscopes (SEM) image of the AOGs of the piezoelectric film 114. It is clear that the misorienting of the bottom electrode 112 leads to significant AOGs of the piezoelectric film 14 in forms of crystallites, which will result in increased material losses in the BAW resonator 100.

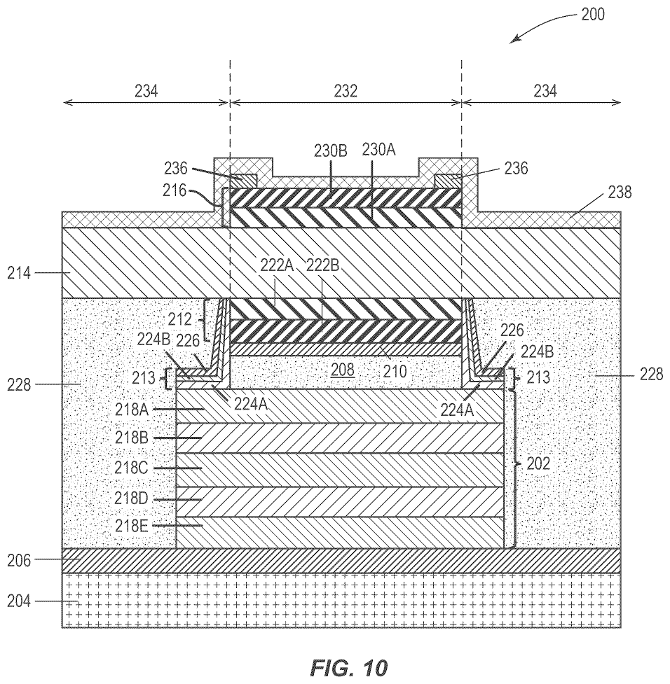

FIG. 10 illustrates a cross-sectional diagram illustrating an exemplary BAW resonator 200, which is capable of reducing electrical losses for high frequency applications without suffering extra material losses according to embodiments of the present disclosure. For the purpose of this illustration, the BAW resonator 200 includes a bottom reflector 202, a substrate 204 underneath the bottom reflector 202, an ESD protection layer 206 vertically between the substrate 204 and the bottom reflector 202, a bottom dielectric layer 208 over the bottom reflector 102, a seed layer 210 over the bottom dielectric layer 208, a bottom electrode 212 over the seed layer 210, a bottom connection structure 213 configured to provide an electrical connection between the bottom electrode 212 and the bottom reflector 202, a piezoelectric film 214 over the bottom electrode 212, and a top electrode 216 over the piezoelectric film 214.

In some embodiments, the bottom reflector 202 is a Bragg reflector and is composed of a stack of reflector layers 218A through 218E (referred to generally as reflector layers 218), each of which is electrically conductive. The reflector layers 218 alternate between different electrically conductive materials (e.g. different metal materials) having high and low acoustic impedances, so as to produce a significant reflection coefficient at a junction of adjacent reflector layers 218. The electrically conductive materials with high acoustic impedance may be W, Mo, or Pt, and the electrically conductive materials with low acoustic impedance may be aluminum (Al) or titanium (Ti). In a non-limited example, a first reflector layer 218A at a top portion of the bottom reflector 202 is formed of W, a second reflector layer 218B directly underneath the first reflector layer 218A is formed of Al, a third reflector layer 218C directly underneath the second reflector layer 218B is formed of W, a fourth reflector layer 218D directly underneath the third reflector layer 218C is formed of Al, and a fifth reflector layer 218C, which is directly underneath the fourth reflector layer 218D and directly over the ESD protection layer 206, is formed of W. While only five reflector layers 218 are illustrated in FIG. 10, the number of reflector layers 218 and the sequence of high/low impedance materials within the bottom reflector 202 will vary from one design to another.

The substrate 204 may be formed of silicon, or other suitable carrier materials. The ESD protection layer 206 located vertically between the bottom reflector 202 and the substrate 204 is an electrically insulating layer configured to isolate the bottom reflector 202 from the substrate 204. The ESD protection layer 206 may be formed of aluminum nitride (AlN), silicon oxide, silicon nitride, or any other dielectric material. In some embodiments, the ESD protection layer 206 may have high breakdown strength (e.g., achieving a breakdown voltage of at least 400 V or at least 500V with a thickness as thin as 200 nm) and a relatively high thermal conductivity (e.g., larger than 300 W/mK). For a non-limited example, the ESD protection layer 206 is formed of AlN with a thickness up to 1.5 μm (e.g., 200 nm and 1000 nm).

The bottom dielectric layer 208 is formed directly over the first reflector

layer 218A without fully covering a top surface of the first reflector layer 218A (i.e., a top surface of the bottom reflector 202). The bottom dielectric layer 208 may be formed of SiO₂ and is configured to compensate for a frequency shift of the BAW resonator 200 caused by the bottom metal reflector 202. The seed layer 210 is formed over a top surface of the bottom dielectric layer 208 without extending laterally beyond the bottom dielectric layer 208. The seed layer 110 may be formed of AlN and is configured to accommodate the bottom electrode 212.

The bottom electrode 212 is formed directly over the seed layer 210 without extending laterally beyond the seed layer 210. Herein, a periphery of the bottom electrode 212, a periphery of the seed layer 210, and a periphery of the bottom dielectric layer 208 are coincidental (i.e., the bottom electrode 212, the seed layer 210, and the bottom dielectric layer 208 have same dimensions in a horizontal plane). The seed layer 210 and the bottom electrode 212 can be deposited in-situ, so as to maintain the pristine nature of the bottom electrode 212 to provide a superior growth condition for the piezoelectric film 214 (more details are described below). In some embodiments, the bottom electrode 212 is composed of two bottom electrode layers 222 (e.g., a first bottom electrode layer 222A and a second bottom electrode layer 222B). The second bottom electrode layer 222B is directly and fully covering a top surface of the seed layer 210 and may be formed of aluminum copper (AICu). The first bottom electrode layer 222A is directly and fully covering a top surface of the second bottom electrode layer 222B and may be formed of W, Mo, or Pt.

Notice that the bottom electrode 212 is not directly connected to the bottom reflector 202 but separated by the seed layer 210 and the bottom dielectric layer 208. In order to electrically connect the bottom electrode 212 to the bottom reflector 202 so as to form a thicker effective bottom electrode (electrode +reflector) for reduced resistance/electrical losses, the bottom connection structure 213 is introduced. The bottom connection structure 213 extends from the bottom electrode 212 towards the bottom reflector 202 and is configured to provide an electrical connection between the bottom electrode 212 and the bottom reflector 202. In one embodiment, the bottom connection structure 213 directly covers side surfaces of the bottom electrode 212 (side surfaces of the first and second bottom electrode layers 222A and 222B), side surfaces of the seed layer 210, and side surfaces of the bottom dielectric layer 208, and extends directly over the portions of the top surface of the bottom reflector 202, which are not covered by the combination of the bottom electrode 212, the seed layer 210, and the bottom dielectric layer 208. The bottom connection structure 213 may include a first connection layer 224A and a second connection layer 224B, each of which may be formed of one conductive material. The first connection layer 224A, which may be formed of Al, directly covers the side surfaces of the bottom electrode 212, the seed layer 210, and the bottom dielectric layer 208, and extends directly over the portions of the top surface of the bottom reflector 202, which are not covered by the combination of the bottom electrode 212, the seed layer 210, and the bottom dielectric layer 208. The second connection layer 224B, which may be formed of W, directly and fully covers the first connection layer 224A. The thicknesses of the first connection layer 224A and the second connection layer 224B can be varied and based on a thickness of the bottom dielectric layer 208.

Since the first connection layer 224A and the second connection layer 224B are formed of metal materials and in contact with both the bottom electrode 212 and the bottom reflector 202, the bottom electrode 212 and the bottom reflector 202 are electrically connected. In some cases, the bottom connection structure 213 may further include a barrier layer 226, which is utilized during oxide polishing (more details described in the following paragraphs). The barrier layer 226 may be formed of AlN and directly and fully covers the second connection layer 224B.

In order to meet certain acoustic performance requirements (e.g., high frequency filtering), the bottom electrode 212 may have a relatively thin thickness (e.g., as thin as 50 nm, and sometimes less than 50 nm). It is because the resonance frequency of one BAW resonator is very sensitive to the thickness of the bottom electrode 212, where a small thickness increment of the bottom electrode 212 may result in a significant reduction in frequency. However, the reduced thickness of the bottom electrode 212 will lead to an undesired large resistance/electrical loss of the bottom electrode 212. Herein, by utilizing the bottom connection structure 213 to electrically connect the bottom electrode 212 with the bottom reflector 202, a thicker effective electrode (the bottom electrode 212+the bottom reflector 202) can be achieved. Since the bottom reflector 202 is formed of metal materials, the current received from the bottom electrode 212 can pass through a combination of the bottom electrode 212 and the bottom reflector 202, and thus the resistance/electrical loss can be significantly reduced.

Note that compared to the bottom electrode 212, the bottom reflector 202 is far away from the piezoelectric film 214, such that the thickness of the bottom reflector 202 has a relatively small impact on the resonance frequency. The bottom dielectric layer 208 formed over the bottom reflector 202 is configured to compensate for a frequency shift caused by the bottom reflector 202. In addition, the ESD protection layer 206 isolates the bottom reflector 202 from the substrate 204, so as to avoid undesired shorting to other electronic components formed on the substrate 204 (not shown).

A combination of the bottom reflector 202, the bottom dielectric layer 208, the seed layer 210, the bottom electrode 212, and the bottom connection structure 213 is capable of meeting the certain acoustic performance requirements without sacrificing an increase in electrical losses. In addition, by utilizing the bottom connection structure 213, the bottom electrode 212 can be deposited in-situ with the seed layer 210 to maintain its pristine nature and still be electrically connected to the bottom reflector 202 for reduced resistance. In consequence, the piezoelectric film 214 grown on the in-situ deposited bottom electrode 212 will be of good quality (e.g., fewer AOGs).

The piezoelectric film 214 is formed directly over the bottom electrode 212. The piezoelectric film 214 may have a thickness between 0.1 μm and 1.4 μm and may be formed of AlN, scandium-doped aluminum nitride (ScAlN), magnesium hydrofluoric acid aluminum nitride (MgHfAlN), magnesium zirconium aluminum nitride (MgZrAlN), or magnesium titanium aluminum nitride (MgTiAlN). In some applications, the BAW resonator 200 may also include a bottom isolation section 228 filled vertically between the piezoelectric film 214 and the substrate 204/the ESD protection layer 206 to surround the combination of the bottom reflector 202, the bottom dielectric layer 208, the seed layer 210, the bottom electrode 212, and the bottom connection structure 213. The bottom isolation section 228 may be formed of silicon oxide.

The top electrode 216 is formed over the piezoelectric film 214 and is vertically aligned with the bottom electrode 212. The top electrode 216 may be composed of a first top electrode layer 230A formed directly over the piezoelectric film 214 and a second top electrode layer 230B formed over and fully covering the first top electrode layer 230A. The first top electrode layer 230A may be formed of W, Mo, or Pt, while the second top electrode layer 230B may be formed of AlCu. In some applications, the top electrode 216 may also include an electrode seed layer (not shown) vertically between the first top electrode layer 230A and the second top electrode layer 230B and formed of Titanium Tungsten (TiW) or Titanium (Ti).

The BAW resonator 200 is divided into an active region 232 and an outside region 234. The active region 232 corresponds to a section of the BAW resonator 200 where the top and bottom electrodes 216 and 212 overlap and also includes the layers between and below the overlapping of the top and bottom electrodes 216 and 212. The outside region 234 corresponds to the section of the BAW resonator 200 that surrounds the active region 232. In some applications, a BO ring 236 is formed on or within (not shown) the top electrode 216 to suppress certain spurious modes. The BO ring 236 corresponds to a mass loading of a portion of the top electrodes 216 that extends about a periphery of the active region 232. In this regard, the BO ring 236 may correspond to a thickened portion of the top electrode 216 or the application of additional layers of an appropriate material (e.g. silicon dioxide, silicon nitride, aluminum nitride, or combinations thereof) over the top electrodes 216. In some embodiments, the BO ring 236 may have a dual-step configuration.

Furthermore, within the BAW resonator 200, there might be a passivation layer 238 fully covering the top electrode 216 and the BO ring 236 (if it exists) and portions of a top surface of the piezoelectric film 214 that are not covered by the top electrode 216. The passivation layer 238 may be formed of Silicon Nitride (SiN), SiO₂, or Silicon Oxynitride (SiON), with a thickness between 250 Å and 5000 Å. The passivation layer 238 is configured to protect the BAW resonator 200 from an external environment.

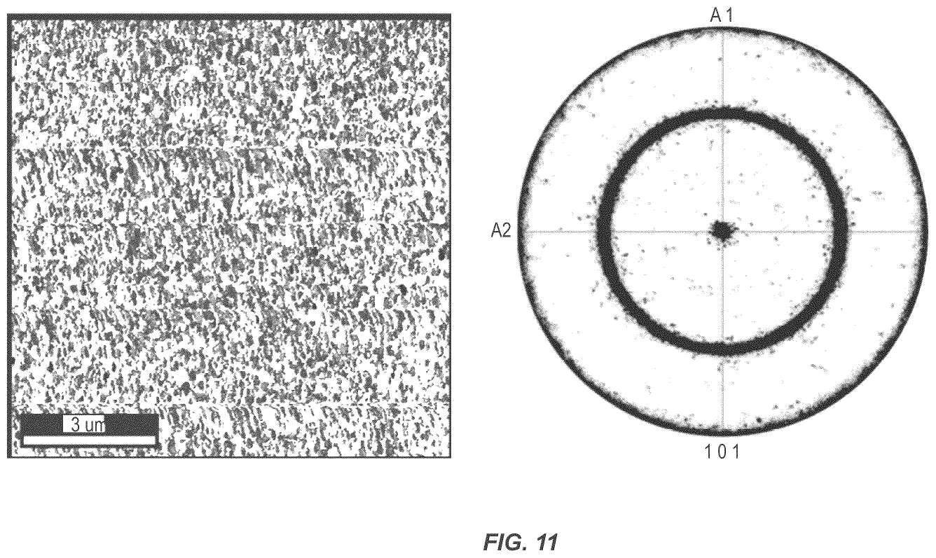

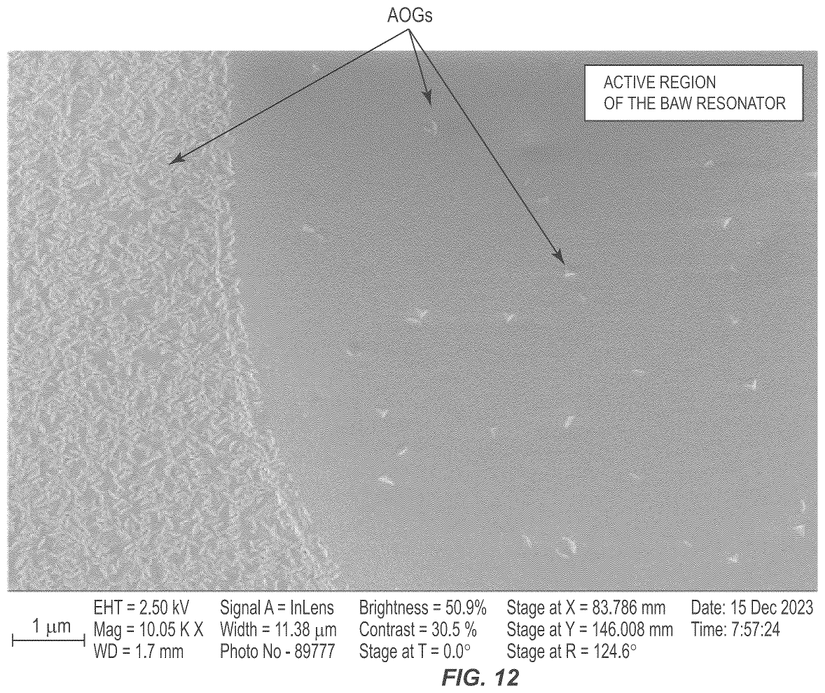

FIG. 11 illustrates EBSD analysis of the bottom electrode 112 of the BAW resonator 200. Herein, more than 90% (e.g., about 94%) of metal grains within the bottom electrode 212 are oriented towards the thermodynamically stable orientation (for a high-quality piezoelectric film growth, this number needs to be greater than 80%). FIG. 12 illustrates an SEM image of the AOGs of the piezoelectric film 214. It is clear that the number of the AOGs of the piezoelectric film 214 within the active region 232 (i.e., the number of the AOGs of portions of the piezoelectric film 214 grown on the in-situ deposited bottom electrode 212) is relatively small (i.e., compared to the piezoelectric film 114 grown on the ex-situ deposited bottom electrode 112, the AOGs of the piezoelectric film 214 within the active region 232 is significantly reduced). Note that the number of the AOGs of the piezoelectric film 214 within the outside region 234 (i.e., the number of the AOGs of portions of the piezoelectric film 214 grown on the bottom isolation section 228) may not be reduced. However, since the outside region 234 has a small impact on the performance of the BAW resonator 200, the number of the AOGs of the piezoelectric film 214 within the outside region 234 will not significantly affect the quality factor of the BAW resonator 200.

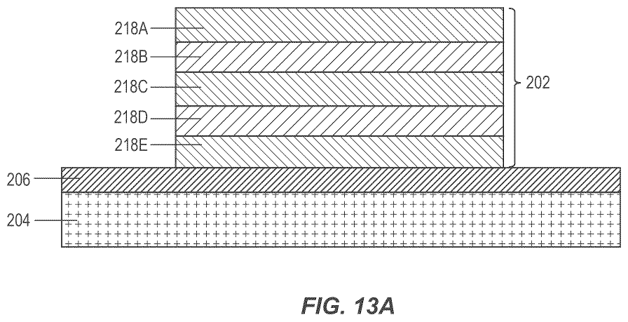

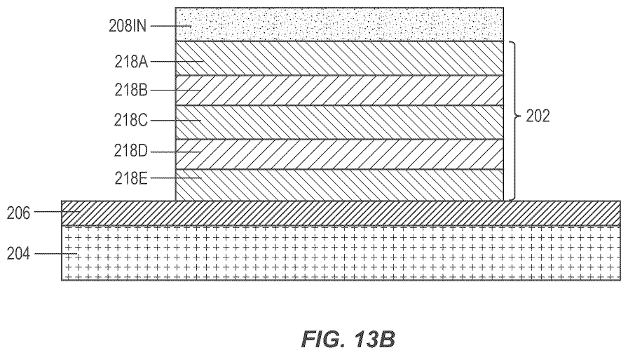

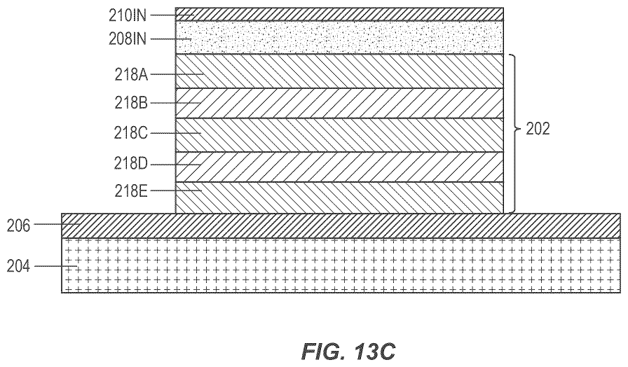

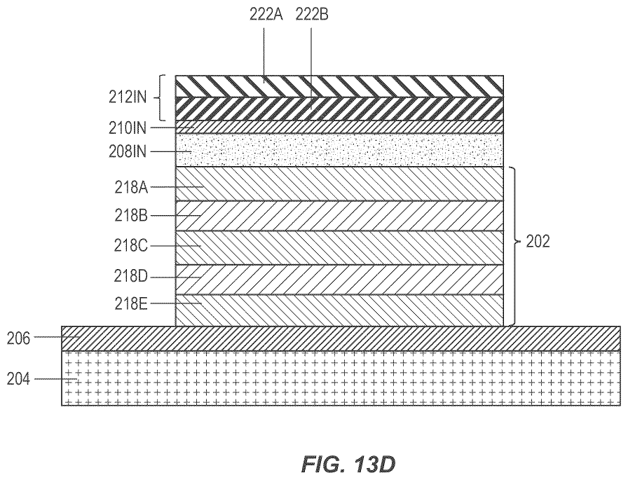

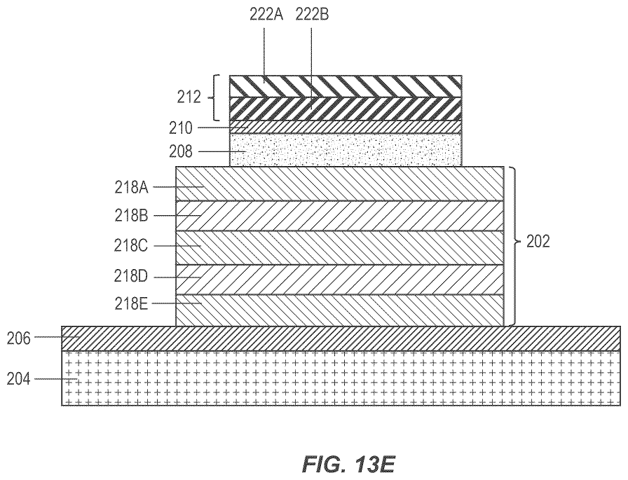

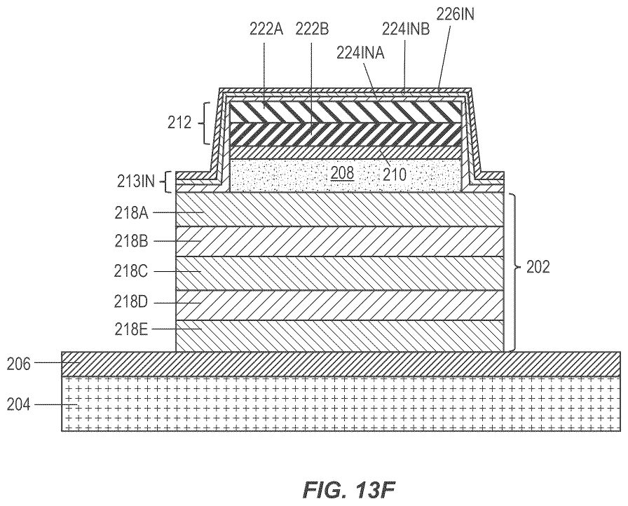

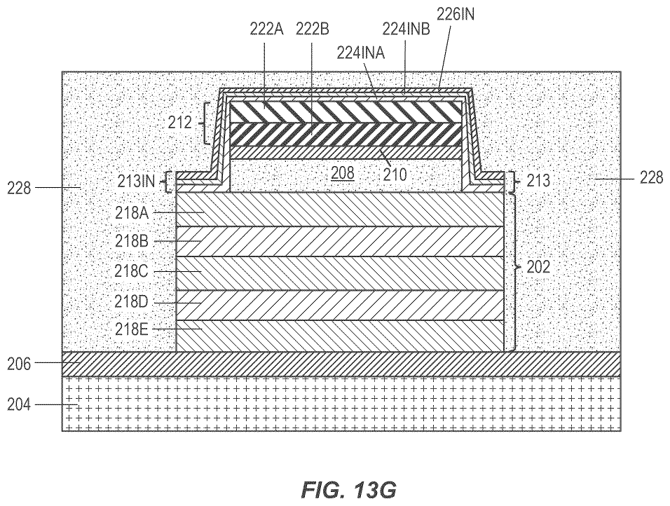

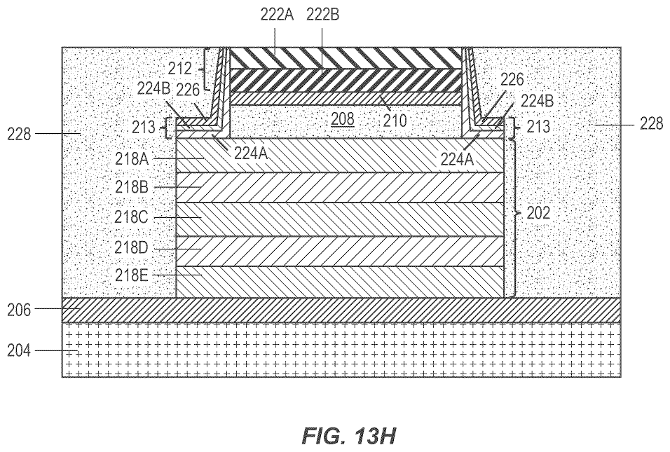

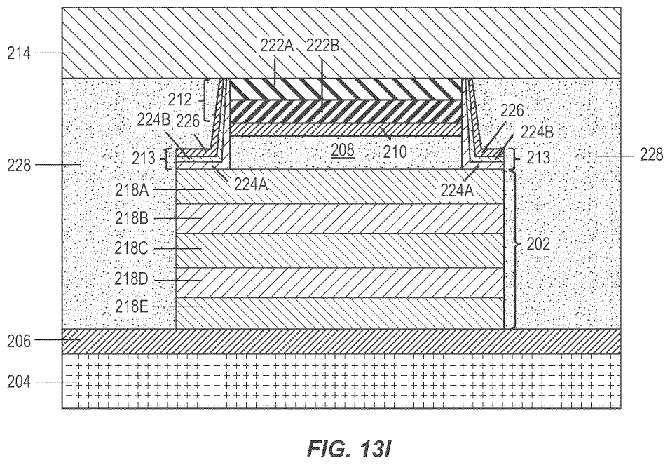

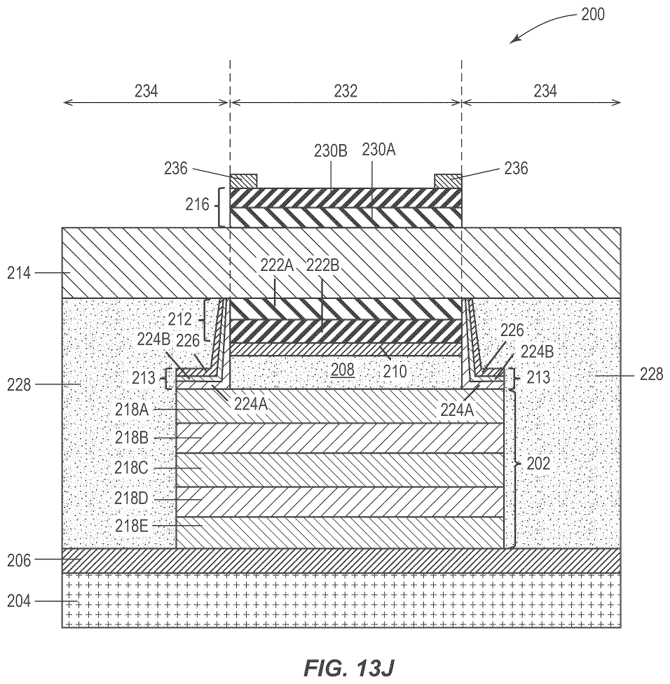

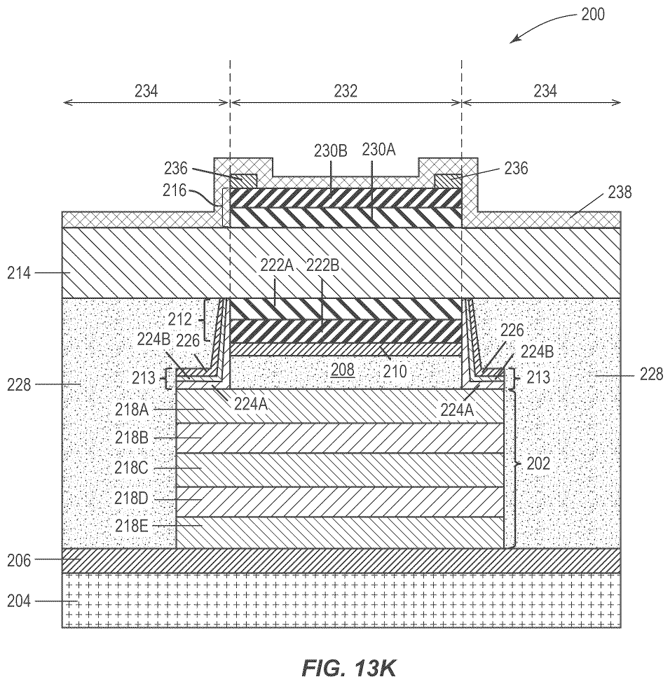

FIGS. 13A-13J show an exemplary fabricating process that illustrates steps to provide the BAW resonator 200 shown in FIG. 10. Although the exemplary steps are illustrated in a series, the exemplary steps are not necessarily order dependent. Some steps may be done in a different order than that presented. Further, processes within the scope of this disclosure may include fewer or more steps than those illustrated in FIGS. 13A-13J.

Initially, the bottom reflector 202 is formed over the substrate 204 via the ESD protection layer 206. The bottom reflector 202 may be a Bragg reflector and is composed of a stack of reflector layers 218 (e.g., 218A-218E). The reflector layers 218 alternate between different electrically conductive materials (e.g. different metal materials) having high and low acoustic impedances, so as to produce a significant reflection coefficient at a junction of adjacent reflector layers 218. The substrate 204 may be formed of silicon, or other suitable carrier materials. The ESD protection layer 206 located vertically between the bottom reflector 202 and the substrate 204 is of an electrical insulating but preferably thermally conductive material (e.g., AlN) and configured to electrically isolate the bottom reflector 202 from the substrate 204.

FIGS. 13B-13D illustrate that an intact bottom dielectric layer 208IN, an intact seed layer 210IN, and an intact bottom electrode 212IN are sequentially deposited in-situ over the bottom reflector 202. The intact bottom dielectric layer 208IN is directly deposited over and fully covers the top surface of the bottom reflector 202. The intact seed layer 210IN is directly deposited over and fully covers a top surface of the intact bottom dielectric layer 208IN. The intact bottom electrode 212IN is directly deposited over and fully covers a top surface of the intact seed layer 210IN. Herein, the depositions of the intact bottom dielectric layer 208IN, the intact seed layer 210IN, and the intact bottom electrode 212IN are continuous without any other processing steps in between. As such, the intact seed layer 210IN is deposited in-situ and maintains its pristine nature, which subsequently leads to well oriented electrode growth of the intact bottom electrode 212IN (e.g., more than 80% of grains within the intact bottom electrode 212IN are oriented towards the thermodynamically stable orientation). In one embodiment, a periphery of the intact bottom dielectric layer 208IN and a periphery of the intact seed layer 210IN, and a periphery of the intact bottom electrode 212IN are coincidental. The intact bottom electrode 212IN is composed of two intact bottom electrode layers 222IN (e.g., a first intact bottom electrode layer 222INA and a second intact bottom electrode layer 222INB). The second intact bottom electrode layer 222INB directly and fully covers the top surface of the intact seed layer 210IN and may be formed of aluminum copper (AICu). The first intact bottom electrode layer 222INA directly and fully covers a top surface of the second intact bottom electrode layer 222INB and may be formed of W, Mo, or Pt.

After the depositions of the intact bottom dielectric layer 208 IN, the intact seed layer 210IN, and the intact bottom electrode 212IN, a combination of the intact bottom dielectric layer 208IN, the intact seed layer 210IN, and the intact bottom electrode 212IN is selectively/partially removed to expose portions of the top surface of the bottom reflector 202, as illustrated in FIG. 13E. In one embodiment, outer regions of the combination are removed, where the intact bottom dielectric layer 208IN, the intact seed layer 210IN, and the intact bottom electrode 212IN are converted into the bottom dielectric layer 208, the seed layer 210, and the bottom electrode 212 (e.g., the first bottom electrode layer 222A and the second bottom electrode layer 222B), respectively. A periphery surface portion of the top surface of the bottom reflector 202 is exposed through a combination of the bottom dielectric layer 208, the seed layer 210, and the bottom electrode 212. Herein, the seed layer 210 maintains its pristine nature, and the bottom electrode 212 maintains well oriented grains (e.g. more than 80% of grains within the bottom electrode 212 are oriented towards the thermodynamically stable orientation).

An intact bottom connection structure 213IN is then formed to provide an electrical connection between the bottom electrode 212 and the bottom reflector 202, as illustrated in FIG. 13F. The intact bottom connection structure 213IN covers the top surface of the bottom electrode 212, extends along the side surfaces of the bottom electrode 212 (side surfaces of the first and second bottom electrode layers 222A and 222B), the side surfaces of the seed layer 210, and the side surfaces of the bottom dielectric layer 208, and extends towards the exposed portions of the top surface of the bottom reflector 202 (i.e., not covered by the combination of the bottom dielectric layer 208, the seed layer 210, and the bottom electrode 212). In one embodiment, the intact bottom connection structure 213IN may include one or more connection layers (e.g., a first intact connection layer 224INA and a second intact connection layer 224INB), each of which may be formed of a conductive material. The first intact connection layer 224INA may be formed of Al, and directly covers the top surface of the bottom electrode 212, the side surfaces of the bottom electrode 212, the seed layer 210, and the bottom dielectric layer 208, and extends directly over the exposed surface portions of the top surface of the bottom reflector 202. The second intact connection layer 224INB may be formed of W and directly and fully covers the first intact connection layer 224INA. Since the first intact connection layer 224INA and the second intact connection layer 224INB are formed of electrically conductive materials and in contact with both the bottom electrode 212 and the bottom reflector 202, the bottom electrode 212 and the bottom reflector 202 are electrically connected. In some applications, the intact bottom connection structure 213IN may further include an intact barrier layer 226IN, which is configured to provide a protection/an indication during a following polishing step (i.e., a polishing step of the bottom isolation section 228, more details are described in the following paragraphs). The intact barrier layer 226IN may be formed of AlN and directly and fully covers the second intact connection layer 224INB.

Next, the bottom isolation section 228 is formed over the ESD protection layer 206 to encapsulate the combination of the bottom reflector 202, the bottom dielectric layer 208, the seed layer 210, the bottom electrode 212, and the intact bottom connection structure 213IN, as illustrated in FIG. 13G. The bottom isolation section 228 may be formed of silicon oxide. A polishing step is followed to thin down the isolation section 228 until a top surface of the bottom electrode 212 is completely exposed, as illustrated in FIG. 13H. Herein, a top portion of the intact bottom connection structure 213IN (i.e., a portion of the intact bottom connection structure 213IN over the top surface of the bottom electrode 212) is completely removed. The barrier layer 226IN is configured to indicate that the polishing process is about to stop. As such, the top surface of the bottom electrode 212 can be completely exposed without (or at least negligibly) thinning down the bottom electrode 212. The polishing step might be implemented by mechanical grinding.

After the grinding, the intact bottom connection structure 213IN is converted to the bottom connection structure 213, which, in one embodiment, includes the first connection layer 224A (converted from the first intact connection layer 224INA), the second connection layer 224B (converted from the second intact connection layer 224INB), and the barrier layer 226 (converted from the intact barrier layer 226IN). The first connection layer 224A still directly covers the side surfaces of the bottom electrode 212, the seed layer 210, and the bottom dielectric layer 208, and extends directly over the exposed surface portions of the top surface of the bottom reflector 202. The second connection layer 224B fully covers the first connection layer 224A, while the barrier layer 226 fully covers the second connection layer 224B. Since the first connection layer 224A and the second connection layer 224B, which are formed of electrically conductive materials, are still in contact with both the bottom electrode 212 and the bottom reflector 202, the bottom connection structure 213 still provides the electrical connection between the bottom electrode 212 and the bottom reflector 202. The electrical connection between the bottom electrode 212 and the bottom reflector 202 results in a significant reduction in resistance/electrical losses, which boosts a quality factor of the final resonator (e.g., the BAW resonator 200). Herein, a top surface of the bottom isolation section 228, the top surface of the bottom electrode 212, and a small portion of the bottom connection structure 213 are planarized in a same horizontal plane.

The piezoelectric film 214 is then grown directly on the top surface of the bottom electrode 212 and the top surface of the bottom isolation section 228, as illustrated in FIG. 131. The piezoelectric film 214 may be formed of AlN, ScAlN, MgHfAlN, MgZrAlN, or MgTiAlN with a thickness between 0.3 μm and 1.4 μm. Since the bottom electrode 212 maintains well-oriented grains, the piezoelectric film 214, at least the portions of the piezoelectric film 214 formed directly over the bottom electrode 212, will have good growth quality (e.g., having small amount of AOGs), which results in a relatively small material loss and thus does not sacrifice the quality factor of the final resonator (e.g., the BAW resonator 200). The thickness of the piezoelectric film 214 may be as-grown/as-deposited, or may be reduced (e.g., the piezoelectric film 214 is milled down) after its growth/deposition.

Once the piezoelectric film 214 is completed, the top electrode 216 and the optional BO ring 236 are formed over the piezoelectric film 214 to complete the BAW resonator 200, as illustrated in FIG. 13J. The top electrode 216 is vertically aligned with the bottom electrode 212 and may be composed of the first top electrode layer 230A directly over the piezoelectric film 214 and the second top electrode layer 230B fully covering and over the first top electrode layer 230A. The first top electrode layer 230A may be formed of W, Mo, or Pt, while the second top electrode layer 230B may be formed of AlCu. In some applications, the top electrode 216 may also include the electrode seed layer (not shown) vertically between the first top electrode layer 230A and the second top electrode layer 230B and formed of TiW or Ti. The overlapping portions of the top and bottom electrodes 216 and 212 and the layers between and below the overlapping of the top and bottom electrodes 216 and 212 are referred to as the active region 232, which is surrounded by the outside region 234. In some applications, the BO ring 236 is formed on or within (not shown) the top electrode 216 to suppress certain spurious modes.

Lastly and optionally, the passivation layer 238 is applied to protect the BAW resonator 200 from an external environment, as illustrated in FIG. 13K. The passivation layer 238 fully covers the top electrode 216 and the BO ring 236 (if it exists) and portions of the top surface of the piezoelectric film 214 that are not covered by the top electrode 216. The passivation layer 238 may be formed of SiN, SiO₂, or SiON, with a thickness between 250 Å and 5000 Å.

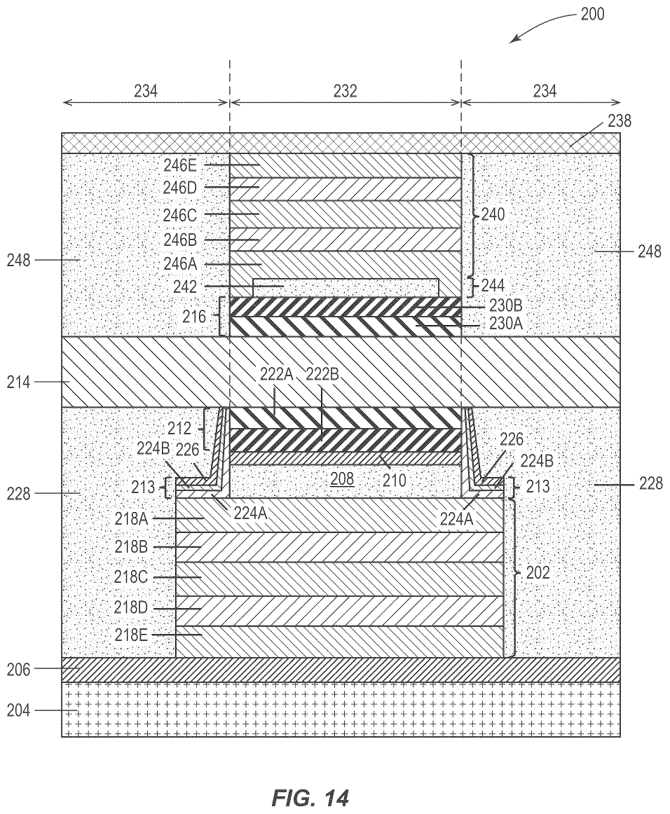

In some applications, the BAW resonator 200 may include two reflectors instead of one reflector, as illustrated in FIG. 14. For the purpose of this illustration, besides the substrate 204, the ESD protection layer 206, the bottom reflector 202, the bottom dielectric layer 208, the seed layer 210, the bottom electrode 212, the bottom connection structure 213, the piezoelectric film 214, and the top electrode 216, the BAW resonator 200 further includes a top reflector 240, a top dielectric layer 242, and a top connection structure 244.

The top dielectric layer 242 is formed directly over the top electrode 216 (i.e., directly over the second top electrode layer 230B) without fully covering a top surface of the top electrode 216. In particular, a peripheral portion of the top surface of the top electrode 216 is not covered by the top dielectric layer 242. The top dielectric layer 242 may be formed of SiO₂.

The top reflector 240, which might be a Bragg reflector and composed of a stack of reflector layers 246A through 246E (referred to generally as reflector layers 246), is formed over the top dielectric layer 242. The reflector layers 246 alternate between different electrically conductive materials (e.g. different metal materials) having high and low acoustic impedances, so as to produce a significant reflection coefficient at a junction of adjacent reflector layers 246. The electrically conductive materials with high acoustic impedance may be W, Mo, or Pt, and the electrically conductive materials with low acoustic impedance may be aluminum (Al) or Ti. In a non-limited example, a first reflector layer 246A that is located at a bottom portion of the top reflector 240 and directly formed over the top dielectric layer 242 is formed of W, a second reflector layer 246B directly over the first reflector layer 246A is formed of Al, a third reflector layer 246C directly over the second reflector layer 246B is formed of W, a fourth reflector layer 246D directly over the third reflector layer 246C is formed of Al, and a fifth reflector layer 246E, which is directly over the fourth reflector layer 246D and at a top portion of the top reflector 240, is formed of W. While only five reflector layers 246 are illustrated in FIG. 14, the number of reflector layers 246 and the sequence of high/low impedance materials within the top reflector 240 will vary from one design to another.

In addition, the top connection structure 244 extends from a peripheral portion of a bottom surface of the first reflector layer 246A, along sides of the top dielectric layer 242, and toward to the peripheral portion of the top surface of the top electrode 216, which is not covered by the top dielectric layer 242. The top connection structure 244 is configured to provide an electrical connection between the top electrode 216 and the top reflector 240. In some embodiments, the top connection structure 244 and the first reflector layer 246A are formed by a same deposition process and include the same conductive material, such as W, Mo, or Pt.

As described above, with the top connection structure 244, the top electrode 216 is electrically connected to the top reflector 240 to achieve a thicker effective top electrode. The current received from the top electrode 216 can pass through a combination of the top electrode 216 and the top reflector 240. As such, acoustic performance requirements (e.g., high frequency operation) can be met without sacrificing electrical loss. In addition, the top dielectric layer 242 is configured to compensate for a frequency shift caused by the top reflector 240. Herein, the active region 232 of the BAW resonator 200 corresponds to a section of the BAW resonator 200 where the top and bottom electrodes 216 and 212 overlap and also includes the layers below, in-between, and above the overlapping top and bottom electrodes 216 and 212. In this illustration, the BO ring 236 is omitted in the BAW resonator 200.

In this illustration, the BAW resonator 200 further includes a top isolation section 248 and the passivation layer 238. The top isolation section 248 surrounds a combination of the top reflector 240, the top electrode 216, the top dielectric layer 242, and the top connection structure 244. The passivation layer 238 is formed over the top isolation section 248 to encapsulate the top reflector 240, so as to protect the BAW resonator 200 from an external environment. The top isolation section 248 may be formed of silicon oxide, while the passivation layer 238 may be formed of SiN, SiO₂, or SiON with a thickness between 250 Å and 5000 Å. In different applications, the top isolation section 248 and the passivation layer 238 might be omitted.

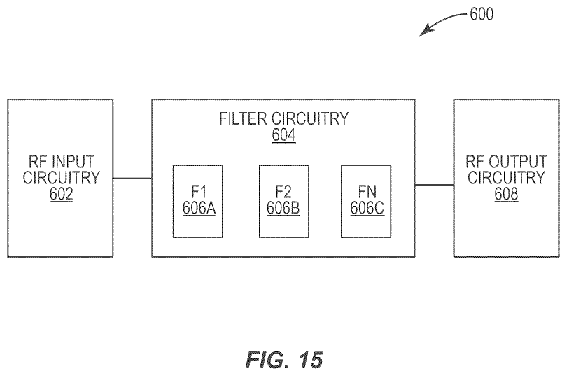

FIG. 15 illustrates a block diagram of an example system 600 that includes at least one BAW resonator 200 shown in FIG. 10 or FIG. 14. The system 600 includes radio frequency (RF) input circuitry 602 connected to filter circuitry 604. In certain embodiments, the RF input circuitry 602 includes a transceiver. For the purpose of this illustration, the filter circuitry 604 includes three filters 606A, 606B, and 606C. Herein, one or more of the filters 606A, 606B, and 606C may be acoustic filters, which are implemented by the BAW resonator 200. In different applications, the filter circuitry 604 may include fewer or more filters. In one embodiment, each of the filters 606A, 606B, and 606C may be a lowpass filter, a high-pass filter, a notch filter, or a bandpass filter, and the RF switch structures 606A, 606B, and 606C may be connected in a cascaded arrangement. The filter types that are included in the filter circuitry 604 may be based at least on the rejection requirements of the system 600.

The filter circuitry 604 is connected to an RF output circuitry 608. In certain embodiments, the RF output circuitry 608 includes an antenna. The RF input circuitry 602 and/or the RF output circuitry 608 may include additional or different components in other embodiments.

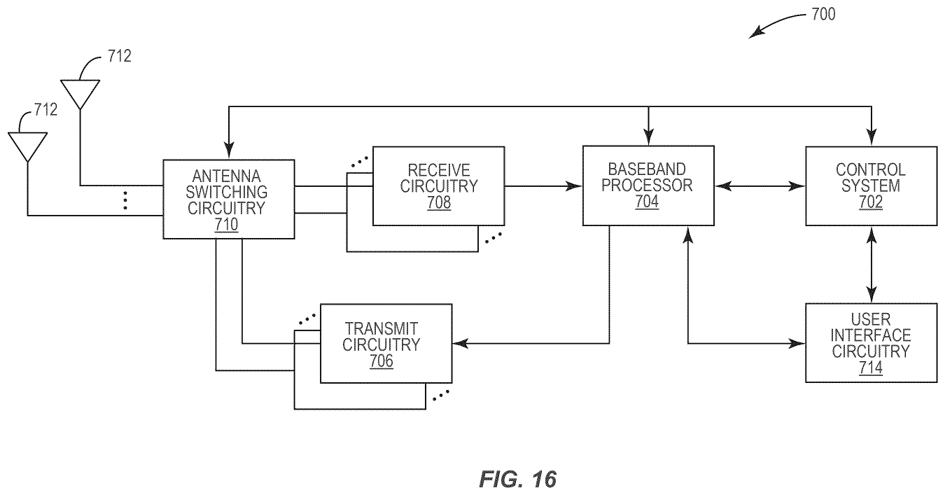

FIG. 16 illustrates a block diagram of an exemplary communication device 700, in which at least one acoustic filter implemented by the BAW resonator 200 as shown in FIG. 10 or FIG. 14 can be provided. Herein, the communication device 700 can be any type of communication device, such as a mobile terminal, smart watch, tablet, computer, navigation device, access point, base station (e.g., eNB or gNB), and any other type of wireless communication devices that support wireless communications, such as cellular, wireless local area network (WLAN), Bluetooth, Ultra-wideband (UWB), and near field communications. The communication device 700 will generally include a control system 702, a baseband processor 704, transmit circuitry 706, receive circuitry 708, antenna switching circuitry 710, multiple antennas 712, and user interface circuitry 714. In a non-limiting example, the control system 702 can be a field-programmable gate array (FPGA) or an application-specific integrated circuit (ASIC), as an example. In this regard, the control system 702 can include at least a microprocessor(s), an embedded memory circuit(s), and a communication bus interface(s). The receive circuitry 708 receives radio frequency signals via the antennas 712 and through the antenna switching circuitry 710 from one or more base stations. A low noise amplifier and a filter of the receive circuitry 708 cooperate to amplify and remove broadband interference from the received signal for processing. Down conversion and digitization circuitry (not shown) will then down convert the filtered, received signal to an intermediate or baseband frequency signal, which is then digitized into one or more digital streams using an analog-to-digital converter(s) (ADC).

The baseband processor 704 processes the digitized received signal to extract the information or data bits conveyed in the received signal. This processing typically comprises demodulation, decoding, and error correction operations, as will be discussed in greater detail below. The baseband processor 704 is generally implemented in one or more digital signal processors (DSPs) and ASICs.

For transmission, the baseband processor 704 receives digitized data, which may represent voice, data, or control information, from the control system 702, which it encodes for transmission. The encoded data is output to the transmit circuitry 706, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal to the antennas 712 through the antenna switching circuitry 710. The multiple antennas 712 and the replicated transmit and receive circuitries 706, 708 may provide spatial diversity. Modulation and processing details will be understood by those skilled in the art. In some embodiments, the at least one acoustic filter implemented by the BAW resonator 200 may be provided in any one or more of the circuitries in the communication device 700, such as the transmit circuitry 706, the receive circuitry 708, and/or the antenna switching circuitry 710.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A bulk acoustic wave (BAW) resonator, comprising:
a bottom reflector including a stack of alternating high acoustic impedance conductive layers and low acoustic impedance conductive layers;
a bottom dielectric layer formed directly over the bottom reflector;
a seed layer formed directly over the bottom dielectric layer;
a bottom electrode comprising metal materials and formed directly over the seed layer, wherein:
a periphery of the bottom electrode, a periphery of the seed layer, and a periphery of the bottom dielectric layer are coincidental;
a combination of the bottom electrode, the seed layer, and the bottom dielectric layer partially covers a top surface of the bottom reflector; and.
at least 80% of metal grains in the bottom electrode are oriented within 3 degrees towards a thermodynamically stable orientation of the metal materials in the bottom electrode;
a bottom connection structure configured to provide an electrical connection between the bottom electrode and the bottom reflector, and having a different layer configuration than the bottom electrode;
a piezoelectric film formed over the bottom electrode; and
a top electrode formed over the piezoelectric film and aligned with the bottom electrode.

2. The BAW resonator of claim 1 wherein:
the seed layer is formed of aluminum nitride (AlN);
the bottom electrode is composed of at least a first bottom electrode layer and a second bottom electrode layer;
the second bottom electrode layer directly and fully covers a top surface of the seed layer and is formed of aluminum copper (AlCu), while the first bottom electrode layer fully covers a top surface of the second bottom electrode layer and is formed of tungsten (W), molybdenum (Mo), or platinum (Pt); and
the piezoelectric film is formed of one of a group consisting of AlN, scandium-doped aluminum nitride (ScAlN), magnesium hydrofluoric acid aluminum nitride (MgHfAlN), magnesium zirconium aluminum nitride (MgZrAlN), and magnesium titanium aluminum nitride (MgTiAlN).

3. The BAW resonator of claim 2 wherein the bottom electrode has a thickness as thin as 50 nm.

4. The BAW resonator of claim 3 wherein the piezoelectric film has a thickness between 0.1 μm and 1.4 μm.

5. The BAW resonator of claim 1 wherein:
the bottom connection structure comprises one or more metal materials; and
the bottom connection structure directly covers side surfaces of the bottom electrode, side surfaces of the seed layer, and side surfaces of the bottom dielectric layer, and extends directly over portions of the top surface of the bottom reflector, which are not covered by the combination of the bottom electrode, the seed layer, and the bottom dielectric layer.

6. The BAW resonator of claim 5 wherein:
the bottom connection structure includes a first connection layer and a second connection layer, each of which is formed of a metal material;
the first connection layer directly covers the side surfaces of the bottom electrode, the side surfaces of the seed layer, and the side surfaces of the bottom dielectric layer, and extends directly over the portions of the top surface of the bottom reflector, which are not covered by the combination of the bottom electrode, the seed layer, and the bottom dielectric layer; and
the second connection layer directly and fully covers the first connection layer.

7. The BAW resonator of claim 6 wherein:
the first connection layer is formed of aluminum (Al); and
the second connection layer is formed of tungsten (W).

8. The BAW resonator of claim 7 wherein the bottom connection structure further includes a barrier layer formed of aluminum nitride (AlN), which directly and fully covers the second connection layer.

9. The BAW resonator of claim 1 further comprising a substrate, and an electrostatic discharge (ESD) protection layer, wherein:
the ESD protection layer is an electrically insulating layer and formed over the substrate; and
the bottom reflector is formed over the ESD protection layer, such that the ESD protection layer isolates the substrate from the bottom reflector.

10. The BAW resonator of claim 9 wherein the ESD protection layer is formed of aluminum nitride (AlN), silicon oxide, or silicon nitride.

11. The BAW resonator of claim 9 further comprising a bottom isolation section filled vertically between the piezoelectric film and the ESD protection layer to surround a combination of the bottom reflector, the bottom dielectric layer, the seed layer, the bottom electrode, and the bottom connection structure, wherein the bottom isolation section is formed of silicon oxide.

12. The BAW resonator of claim 1 wherein:
the high acoustic impedance conductive layers are formed of tungsten (W), molybdenum (Mo), or platinum (Pt); and
the low acoustic impedance conductive layers are formed of aluminum (Al) or titanium (Ti).

13. The BAW resonator of claim 1 wherein:
the top electrode is composed of at least a first top electrode layer and a second top electrode layer;
the first top electrode layer is formed directly over the piezoelectric film, and the second top electrode layer is formed over the first top electrode layer; and
the first top electrode layer is formed of tungsten (W), molybdenum (Mo), or platinum (Pt), and the second top electrode layer is formed of aluminum copper (AlCu).

14. The BAW resonator of claim 13 further comprising a border ring (BO) formed on or within the top electrode to suppress spurious modes.

15. The BAW resonator of claim 1 further comprising a top reflector, wherein:
the top reflector includes a stack of alternating high acoustic impedance conductive layers and low acoustic impedance conductive layers; and
the top reflector is formed over and electrically connected to the top electrode.

16. The BAW resonator of claim 15 further comprising a top dielectric layer and a top connection structure, wherein:
the top dielectric layer is formed directly over and partially covers the top electrode, such that a peripheral portion of a top surface of the top electrode is not covered by the top dielectric layer;
the top reflector is formed directly over the top dielectric layer;
the top connection structure extends from a peripheral portion of a bottom surface of the top reflector, along sides of the top dielectric layer, and toward to the peripheral portion of the top surface of the top electrode, which is not covered by the top dielectric layer; and
the top connection structure is configured to electrically connect the top electrode with the top reflector.

17. The BAW resonator of claim 16 wherein the top connection structure and a bottommost one of the alternating high acoustic impedance conductive layers and low acoustic impedance conductive layers are formed of a same conductive material.

18. A method of fabricating a bulk acoustic wave (BAW) resonator comprising:
depositing an intact bottom dielectric layer to directly and fully cover a top surface of a bottom reflector, which includes a stack of alternating high acoustic impedance conductive layers and low acoustic impedance conductive layers;
depositing an intact seed layer to directly and fully cover the intact bottom dielectric layer;
depositing an intact bottom electrode in-situ to directly and fully cover the intact seed layer, wherein the intact bottom electrode comprises metal materials, and at least 80% of metal grains in the intact bottom electrode are oriented within 3 degrees towards a thermodynamically stable orientation of the metal materials in the bottom electrode;
selectively removing a combination of the intact bottom dielectric layer, the intact seed layer, and the intact bottom electrode to expose portions of the top surface of the bottom reflector, wherein the intact bottom dielectric layer, the intact seed layer, and the intact bottom electrode are converted into a bottom dielectric layer, a seed layer, and a bottom electrode, respectively;
forming a bottom connection structure configured to provide an electrical connection between the bottom electrode and the bottom reflector, wherein:
the bottom connection structure directly covers side surfaces of the bottom electrode, side surfaces of the seed layer, and side surfaces of the bottom dielectric layer, and extends directly over the exposed portions of the top surface of the bottom reflector; and
a top surface of the bottom electrode is not covered by the bottom connection structure; and
forming a piezoelectric film over the top surface of the bottom electrode.

19. The method of claim 18 wherein the bottom connection structure has a different layer configuration than the bottom electrode.

20. The method of claim 18 wherein forming the bottom connection structure comprises:
forming an intact bottom connection structure, which covers the top surface of the bottom electrode, extends along the side surfaces of the bottom electrode, the side surfaces of the seed layer, and the side surfaces of the bottom dielectric layer, and extends directly over the exposed portions of the top surface of the bottom reflector; and
performing a polishing step to remove a top portion of the intact bottom connection structure to expose the top surface of the bottom electrode, wherein the intact bottom connection structure is converted into the bottom connection structure.

21. The method of claim 20 further comprising:
providing a substrate;
forming an electrostatic discharge (ESD) protection layer over the substrate, wherein the bottom reflector is formed over the ESD protection layer; and
forming a bottom isolation section after the intact bottom connection structure is formed, wherein:
the bottom isolation section is formed over the ESD protection layer to completely encapsulate a combination of the bottom reflector, the bottom dielectric layer, the seed layer, the bottom electrode, and the intact bottom connection structure; and
the polishing step is performed to thin down the bottom isolation section until the top portion of the intact bottom connection structure is removed, thereby exposing the top surface of the bottom electrode.

22. The method of claim 18 further comprising forming a top electrode, which is over the piezoelectric film and aligned with the bottom electrode.

23. The method of claim 18 wherein:
the bottom connection structure includes a first connection layer and a second connection layer, each of which is formed of a metal material;
the first connection layer directly covers the side surfaces of the bottom electrode, the side surfaces of the seed layer, and the side surfaces of the bottom dielectric layer, and extends directly over the exposed portions of the top surface of the bottom reflector; and
the second connection layer directly and fully covers the first connection layer.

24. The method of claim 22 wherein:
the first connection layer is formed of aluminum (Al); and
the second connection layer is formed of tungsten (W).

25. A system, comprising:
radio-frequency (RF) input circuitry;
RF output circuitry; and
filter circuitry, which includes at least one bulk acoustic wave (BAW) resonator, connected between the RF input circuitry and the RF output circuitry, wherein the at least one BAW resonator comprises:
a bottom reflector including a stack of alternating high acoustic impedance conductive layers and low acoustic impedance conductive layers;
a bottom dielectric layer formed directly over the bottom reflector;
a seed layer formed directly over the bottom dielectric layer;
a bottom electrode comprising metal materials and formed directly over the seed layer, wherein:
a periphery of the bottom electrode, a periphery of the seed layer, and a periphery of the bottom dielectric layer are coincidental;
a combination of the bottom electrode, the seed layer, and the bottom dielectric layer does not fully cover a top surface of the bottom reflector; and
at least 80% of metal grains in the bottom electrode are oriented within 3 degrees towards a thermodynamically stable orientation of the metal materials in the bottom electrode;
a bottom connection structure configured to provide an electrical connection between the bottom electrode and the bottom reflector, and having a different layer configuration than the bottom electrode;
a piezoelectric film formed over the bottom electrode; and
a top electrode formed over the piezoelectric film and aligned with the bottom electrode.
